(19) United States
(12) Patent Application Publication
(10) Pub. No.: US 2024/0334785 A1
(43) Pub. Date: Oct. 3, 2024

(54) DISPLAY DEVICE AND METHOD OF FABRICATING THE SAME

(71) Applicant: SAMSUNG DISPLAY CO., LTD., YONGIN-SI (KR)

(72) Inventor: Jin Yong LEE, Yongin-si (KR)

(21) Appl. No.: 18/502,056

(22) Filed: Nov. 5, 2023

(30) Foreign Application Priority Data
Apr. 3, 2023 (KR) 10-2023-0043338

(51) Int. Cl. H10K 59/80; H10K 59/38; H10K 71/10

(52) U.S. Cl. CPC H10K 59/873; H10K 59/38; H10K 59/877; H10K 71/10; H10K 2102/351

(57) ABSTRACT

A display device includes: an emission material; and an encapsulation structure disposed on the emission material layer and comprising a scattering layer, a first inorganic film disposed on the scattering layer, an organic film disposed on the first inorganic film, and a second inorganic film disposed on the organic film, wherein the scattering layer comprises a plurality of convex portions.

This application claims priority under 35 U.S.C. § 119 to Korean Patent Application No. 10-2023-0043338, filed on Apr. 3, 2023, in the Korean Intellectual Property Office, the disclosure of which is incorporated by reference herein in its entirety.

### BACKGROUND

### 1. Technical Field

The present disclosure relates to a display device, and a method of fabricating the same.

### 2. Discussion of Related Art

Display devices become more important as multimedia technology evolves. Accordingly, a variety of display devices are currently being developed. For example, display devices such as liquid-crystal display devices (LCDs) and organic light-emitting diode display devices (OLEDs) may be developed for a multimedia technology.

Among display devices, a self-luminous display device includes a self-luminous element. The self-luminous element may include two opposing electrodes and an emissive layer interposed therebetween. For an organic light-emitting element configured as a self-luminous element, electrons and holes supplied from the two electrodes are recombined in the emissive layer to generate excitons. Light can be emitted as the generated excitons relax from the excited state to the ground state. Since such an organic light-emitting element is vulnerable to oxygen and moisture, an encapsulation structure may be included to prevent permeation of oxygen and moisture.

A display device may include color conversion elements that receive light from organic light-emitting elements to produce light of different colors. For example, the color conversion elements may receive blue light from organic light-emitting elements and output blue, green and red light, respectively, so that images having various colors can be generated and viewed. The color conversion elements may be disposed in a display device as a separate substrate or may be integrated with elements in the display device.

### SUMMARY

Aspects of the present disclosure provide a display device with improved luminous efficiency by way of forming a scattering layer working as a guide film in an encapsulation structure that may increase the light reaching the color conversion elements, and a method of fabricating the same.

Aspects of the present disclosure also provide a display device that can reduce or prevent external light from being reflected and recognized by a user by way of forming a scattering layer working as an anti-reflection film in an encapsulation structure, and a method of fabricating the same.

Aspects of the present disclosure also provide a method of fabricating a display device in which an improved encapsulation structure may be formed.

It should be noted that aspects of the present disclosure are not limited, and other aspects of the present disclosure will be apparent to those skilled in the art from the following descriptions.

According to an aspect of the present disclosure, there is provided a display device comprising, an emission material layer, and an encapsulation structure disposed on the emission material layer and comprising a scattering layer, a first inorganic film disposed on the scattering layer, an organic film disposed on the first inorganic film, and a second inorganic film disposed on the organic film, wherein the scattering layer comprises a plurality of convex portions.

In an embodiment, the plurality of convex portions comprise, first particles comprising a same material as the first inorganic film, and second particles comprising a material different from that of the first particles.

In an embodiment, the first particles comprise at least one of silicon oxide, silicon nitride, or silicon oxynitride.

In an embodiment, the second particles comprise a same material as the first particles, and comprise at least one of silane (SiH₄), nitrous oxide (N₂O), or ammonia (NH₃).

In an embodiment, a thickness of the scattering layer ranges from about 0.3 to 0.75 times a thickness of the first inorganic film.

In an embodiment, the thickness of the scattering layer ranges from about 0.3 μm to 0.5 μm.

In an embodiment, each of the plurality of convex portions have a hemispherical shape.

In an embodiment, an average radius of each of the plurality of convex portions ranges from about 0.15 μm to 0.25 μm.

In an embodiment, the display device further comprises, a first substrate, a circuit layer disposed on the first substrate, wherein the emission material layer is disposed on the circuit layer, a second substrate facing the first substrate and defining a first light-transmitting area, a second light-transmitting area, and a third light-transmitting area, a color filter layer disposed on the second substrate and comprising a first color filter overlapping the first light-transmitting area, a second color filter overlapping the second light-transmitting area, and a third color filter overlapping the third light-transmitting area, a first wavelength conversion layer disposed on the first color filter, a second wavelength conversion layer disposed on the second color filter, and a transparent layer disposed on the third color filter, wherein the scattering layer is disposed between the first wavelength conversion layer, the second wavelength conversion layer and the transparent layer, and the emission material layer.

In an embodiment, the scattering layer is configured to reduce reflectance of external light incident through a display surface.

According to an aspect of the present disclosure, there is provided a method of fabricating a display device, the method comprising, forming an emission material layer, forming a scattering layer on the emission material layer, and forming a first inorganic film on the scattering layer, wherein the forming of the scattering layer comprises ending an injection of a reaction gas simultaneously with or after ending an application of a discharge power and an injection of a discharge gas.

In an embodiment, the forming of the scattering layer comprises starting injection of the reaction gas simultaneously with or before starting the application of the discharge power and the injection of the discharge gas.

In an embodiment, the forming of the first inorganic film comprises, starting a second application of the discharge power and a second injection of the discharge gas after a predetermined period of time from a start of a second injection of the reaction gas, and ending the second application of the discharge power and the second injection of the discharge gas after a predetermined period of time from the end of the second injection of the reaction gas.

In an embodiment, the method further comprises, forming a first substrate and a circuit layer on the first substrate, wherein the emission material layer is formed on the circuit layer, forming an organic film on the first inorganic film, and forming a second inorganic film on the organic film, wherein the forming the second inorganic film comprises, starting a third application of the discharge power and a third injection of the discharge gas simultaneously with or after starting a third injection of the reaction gas, and ending the third application of the discharge power and the injection of the discharge gas simultaneously with or before ending of the third injection of the reaction gas.

In an embodiment, the scattering layer comprises a plurality of convex portions.

In an embodiment, the plurality of convex portions comprise, first particles comprising a same material as the first inorganic film, and second particles comprising a material different from that of the first particles.

In an embodiment, the first particles comprise at least one of silicon oxide, silicon nitride, or silicon oxynitride and the second particles comprise a same material as the first particles, and comprise at least one of silane (SiH₄), nitrous oxide (N₂O), or ammonia (NH₃).

In an embodiment, a thickness of the scattering layer ranges from about 0.3 to 0.75 times a thickness of the first inorganic film.

According to an aspect of the present disclosure, there is provided a method of fabricating a display device, the method comprising, forming a first substrate, a circuit layer on the first substrate, and an emission material layer on the circuit layer, and forming a first inorganic film on the emission material layer, wherein the forming of the first inorganic film comprises ending an injection of a reaction gas after a predetermined period of time from starting an application of the reaction gas, and starting an application of a discharge power and an injection of a discharge gas simultaneously with or after ending the injection of the reaction gas.

In an embodiment, the application of the discharge power and the injection of the discharge gas are ended after a predetermined period of time from the start of the application of the discharge power and the injection of the discharge gas.

According to an embodiment of the present disclosure, it is possible to improve the luminous efficiency of a display device by way of forming a guide film in an encapsulation structure to increase the light reaching the color conversion elements.

According to an embodiment of the present disclosure, it may be possible to reduce or prevent external light from being reflected and recognized by a user by way of forming a scattering layer working as an anti-reflection film in an encapsulation structure of a display device.

According to an embodiment, it may be possible to form a thin encapsulation structure, having high encapsulation performance, in a display device.

It should be noted that effects of the present disclosure are not limited to those described herein and other effects of the present disclosure will be apparent to those skilled in the art from the following descriptions.

### BRIEF DESCRIPTION OF THE DRAWINGS

Aspects and features of the present disclosure will become more apparent by describing in detail embodiments thereof with reference to the attached drawings, in which:

FIG. 1 is a perspective view of a display device according to an embodiment of the present disclosure.

FIG. 2 is a cross-sectional view of a display device taken along line X1-X1′ of FIG. 1.

FIG. 3 is a plan view of a display device according to an embodiment of the present disclosure.

FIG. 4 is a view showing arrangements of lines in a display device according to an embodiment of the present disclosure.

FIG. 5 is an equivalent circuit diagram of a pixel of a display device according to an embodiment of the present disclosure.

FIG. 6 is a plan view schematically showing a display area of a display substrate in a display device according to an embodiment.

FIG. 7 is a plan view showing a display area of a color conversion substrate in the display device according to an embodiment.

FIG. 8 is a cross-sectional view of the display device, taken along line X2-X2′ of FIG. 7.

FIG. 9 is an enlarged view of portion A of FIG. 8.

FIG. 10 is a cross-sectional view illustrating a state in which light may be scattered by a scattering layer according to an embodiment.

FIG. 11 is a flowchart for illustrating a method of fabricating a display device according to an embodiment of the present disclosure.

FIG. 12 is a flowchart for illustrating step S120 according to an embodiment of the present disclosure.

FIG. 13 is a flowchart for illustrating step S130 according to an embodiment of the present disclosure.

FIG. 14 is a view for conceptually illustrating steps S120 and S130 according to an embodiment of the present disclosure.

FIG. 15 is a cross-sectional view for illustrating step S120 according to an embodiment of the present disclosure.

FIG. 16 is a cross-sectional view for illustrating step S120 according to an embodiment of the present disclosure.

FIG. 17 is a cross-sectional view for illustrating step S130 according to an embodiment of the present disclosure.

FIG. 18 is a flowchart for illustrating step S120 according to an embodiment of the present disclosure.

FIG. 19 is a view for conceptually illustrating steps S120 and S130 according to an embodiment of the present disclosure.

FIG. 20 is a flowchart for illustrating step S120 according to an embodiment of the present disclosure.

FIG. 21 is a view for conceptually illustrating steps S120 and S130 according to an embodiment of the present disclosure.

FIG. 22 is a flowchart for illustrating step S120 according to an embodiment of the present disclosure.

FIG. 23 is a view for conceptually illustrating steps S120 and S130 according to an embodiment of the present disclosure.

FIG. 24 is a flowchart for illustrating a method of fabricating a display device according to an embodiment.

FIG. 25 is a flowchart for illustrating step S220 according to an embodiment of the present disclosure.

FIG. 26 is a view for conceptually illustrating step S220 according to an embodiment of the present disclosure.

FIG. 27 is a view for conceptually illustrating step S220 according to an embodiment of the present disclosure.

FIG. 28 is a cross-sectional view illustrating an example of a display device fabricated by a method of fabricating a display device according to an embodiment.

### DETAILED DESCRIPTION

The invention will now be described more fully hereinafter with reference to the accompanying drawings, in which embodiments of the invention are shown. This invention may be embodied in different forms and should not be construed as limited to embodiments set forth herein. Rather, embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, embodiments of the present disclosure will be described in detail with reference to the accompanying drawings.

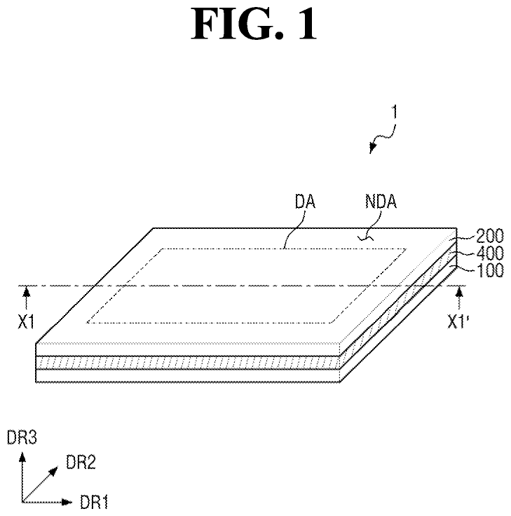

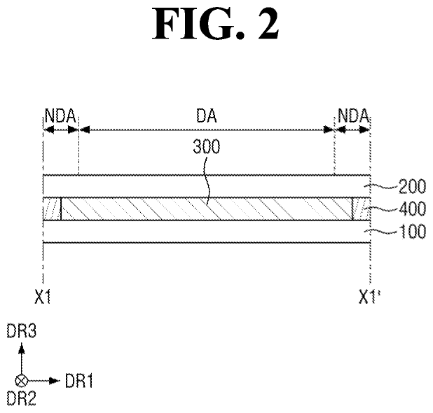

FIG. 1 is a perspective view of a display device according to an embodiment of the present disclosure. FIG. 2 is a cross-sectional view of a display device taken along line X1-X1′ of FIG. 1.

A display device 1 shown in FIG. 1 and FIG. 2 may be employed in a variety of electronic devices including small-and-medium sized electronic devices such as a tablet, a smartphone, a vehicle navigation unit, a camera, a center information display (CID) installed in vehicles, a wrist-type electronic device, a personal digital assistant (PMP), a portable multimedia player (PMP) and a game machine, and medium-and-large electronic devices such as a television, an electric billboard, a monitor, a personal computer (PC) and a laptop computer. It should be understood that these electronic devices are merely illustrative and the display device 1 may be employed in a variety of other electronic devices without departing from the scope of the present disclosure.

According to an embodiment of the present disclosure, the display device 1 may have a rectangular shape when viewed from the top. The display device 1 may include two longer sides extended in a first direction DR1, and two shorter sides extended in a second direction DR2 intersecting the first direction DR1. Although the corners where the longer sides and the shorter sides of the display device 1 meet may form a right angle, this is merely illustrative. The display device 1 may have rounded corners. According to an embodiment, the longer sides may extend in the second direction DR2, and the shorter sides may extend in the first direction DR1. The shape of the display device 1 when viewed from the top is not limited to that shown in the drawings. The display device 1 may have a circular shape or other shapes.

In the drawings, the first direction DR1 and the second direction DR2 intersect each other as the horizontal directions. For example, the first direction D1 and the second direction D2 may be perpendicular to each other. In addition, a third direction DR3 may intersect the first direction DR1 and the second direction DR2, and may be a vertical direction, for example. Herein, a side indicated by the arrow of each of the first to third directions DR1, DR2 and DR3 may be referred to as a first side, while an opposite side may be referred to as a side opposite side unless specifically state otherwise. As used herein, the terms “on,” “upper side,” “above,” “top” and “upper surface” refer to the side indicated by the arrow of the third direction D3 as shown in the drawings. The terms “under,” “lower side,” “below.” “bottom” and “lower surface” refer to the opposite side indicated by the arrow of the third direction D3 as shown in the drawings.

The display device 1 may include a display area DA where images may be displayed, and a non-display area NDA where no image may be displayed. According to an embodiment of the present disclosure, the non-display area NDA may be disposed around the display area DA. The non-display area NDA may surround the display area DA.

According to an embodiment, the display device 1 may include a display substrate 100, and a color conversion substrate 200 opposed to the display substrate 100, and may further include a sealing member 400. The sealing member 400 may couple the display substrate 100 with the color conversion substrate 200. A filler 300 may fill a space between the display substrate 100 and the color conversion substrate 200.

The display substrate 100 may include elements and circuits for displaying images, e.g., a pixel circuit such as a switching element, a pixel-defining layer for defining an emission area and a non-emission area in the display area DA, and a self-luminous element. According to an embodiment, the self-luminous element may include at least one of an organic light-emitting diode, a quantum-dot light-emitting diode, an inorganic-based micro light-emitting diode (e.g., micro LED), or an inorganic-based nano light-emitting diode (e.g., nano LED). In the following description, an organic light-emitting diode will be described as an example of the self-luminous element for convenience of illustration. The present disclosure is not limited thereto, and other self-luminous elements may be used without departing from the scope of the present disclosure.

The color conversion substrate 200 may be located on the display substrate 100 and may face the display substrate 100. According to an embodiment, the color conversion substrate 200 may include a color conversion pattern. The color conversion pattern may convert the color of incident light. According to an embodiment, the color conversion pattern may include at least one of color filters or a wavelength conversion pattern. The color conversion pattern may include at least one of a color filter or a wavelength conversion pattern.

The sealing member 400 may be disposed between the display substrate 100 and the color conversion substrate 30. The sealing member 400 may be disposed in the non-display area NDA. The sealing member 400 may be disposed along the edges of the display substrate 100 and the color conversion substrate 200 in the non-display area NDA. The sealing member 400 may surround the display area DA when viewed from the top. The display substrate 100 and the color conversion substrate 200 may be coupled to each other via the sealing member 400.

According to an embodiment, the sealing member 400 may be made of an organic material. For example, the sealing member 400 may be made of, but is not limited to, an epoxy resin.

The filler 300 may be located in the space between the display substrate 100 and the color conversion substrate 200 surrounded by the sealing member 400. The filler 300 may fill the space between the display substrate 100 and the color conversion substrate 200.

According to an embodiment, the filler 300 may be made of a material that transmits light. According to an embodiment, the filler 300 may be made of an organic material. For example, the filler 300 may be made of, but is not limited to, a silicon-based organic material, an epoxy-based organic material, etc. In an embodiment, the filler 300 may be omitted.

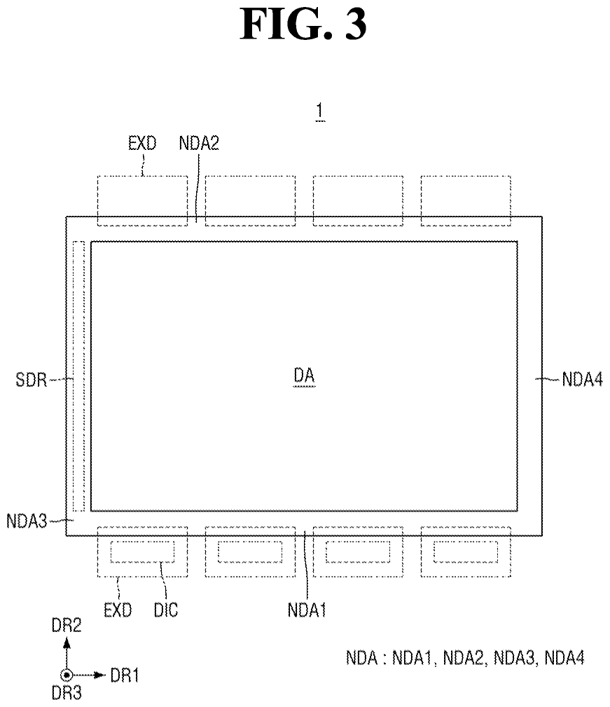

FIG. 3 is a plan view of a display device according to an embodiment of the present disclosure.

According to an embodiment of the present disclosure, the display device 1 may include the display area DA and the non-display area NDA. The display area DA may be an active area where images may be displayed. The display area DA may have, but is not limited to, a rectangular shape similar to the general shape of the display device 1 when viewed from the top.

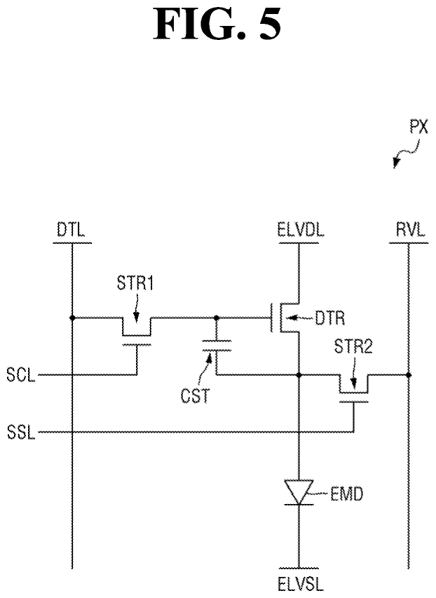

The display area DA may include a plurality of pixels PX (see FIG. 5). The plurality of pixels PX may be arranged in a matrix. The shape of each of the pixels PX may be, but is not limited to, a rectangle or a square when viewed from the top. Each of the pixels PX may have a diamond shape having sides inclined with respect to a side of the display device 1. The plurality of pixels PX may include different color pixels PX. For example, the plurality of pixels PX may include, but is not limited to, a first color pixel, such as a red (R) color pixel, a second color pixel, such as a green (G) color pixel, and a third color pixel, such as a blue (B) color pixel. The color pixels may be arranged repeatedly and sequentially in RGB stripes, in a PenTile matrix, or the like.

The non-display areas NDA may be disposed around the display area DA. The non-display area NDA may surround the display area DA entirely or partially. The display area DA may have a rectangular shape, and the non-display area NDA may be disposed to be adjacent to the sides of the display area DA. The non-display area NDA may form the bezel of the display device 1.

A driving circuit or a driving element for driving the display area DA may be disposed in the non-display areas NDA. According to an embodiment of the present disclosure, a pad area may be disposed on the display substrate of the display device 1 in a first non-display area NDA1 disposed adjacent to a first longer side (the lower side in FIG. 1) of the display device 1 and in a second non-display area NDA2 adjacent to a second longer side (the upper side in FIG. 3) of the display device 1. An external device EXD may be mounted on a pad electrode of the pad area. Examples of the external device EXD may include a connection film, a printed circuit board, a driver chip DIC, a connector, a line connection film, etc. A scan driver SDR may be formed directly on the display substrate of the display device 1 and may be disposed in the third non-display area NDA3 disposed adjacent to a first shorter side of the display device 1 (the left side in FIG. 3). According to an embodiment, a scan driver SDR or the like may be disposed in a fourth third non-display area NDA4 adjacent to a second shorter side (the right side in FIG. 3) of the display device 2.

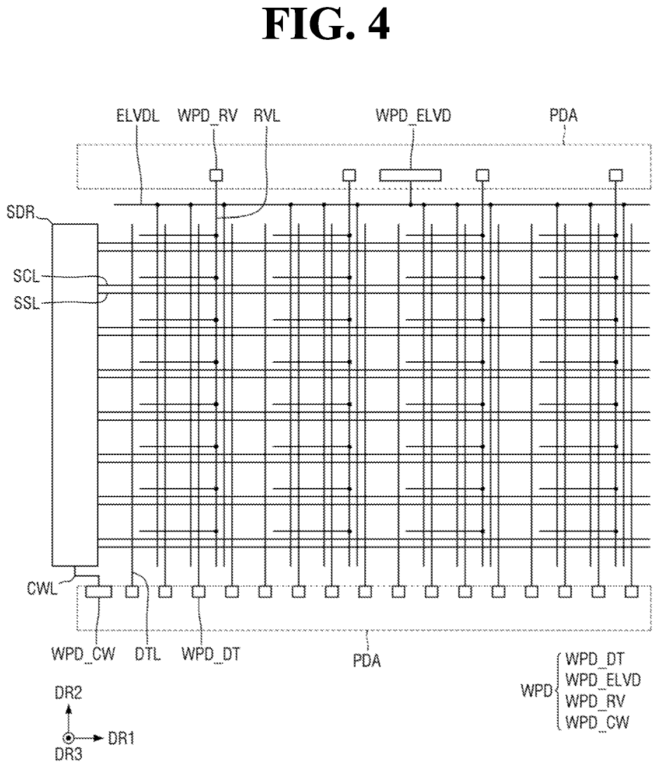

FIG. 4 is a view showing arrangements of lines in a display device according to an embodiment of the present disclosure.

Referring to FIG. 4 in conjunction with FIG. 3, the display device 1 may include a plurality of lines. The plurality of lines may include a scan line SCL, a sensing signal line SSL, a data line DTL, a reference voltage line RVL, a first supply voltage line ELVDL, etc.

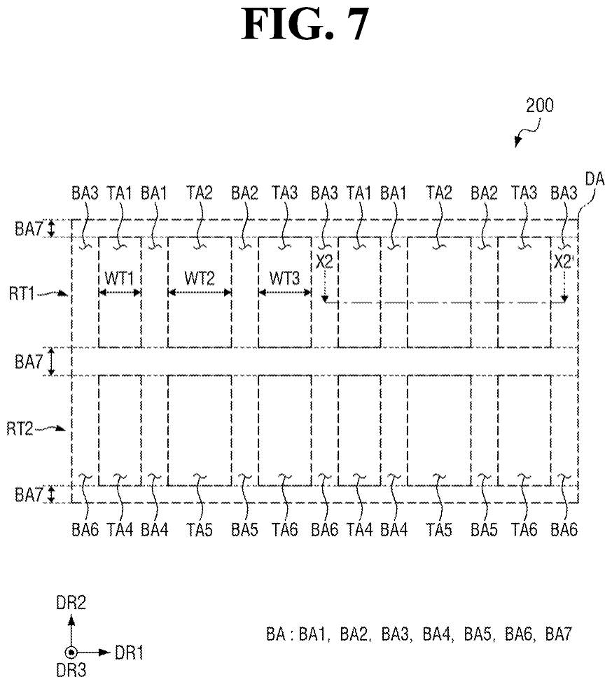

The scan line SCL and the sensing signal line SSL may extend in the first direction DR1. The scan line SCL and the sensing signal line SSL may be connected to the scan driver SDR. The scan driver SDR may include a driving circuit formed of a circuit layer CCL (see FIG. 7). The scan driver SDR may be disposed in the third non-display area NDA3, but the present disclosure is not limited thereto. As an example, the scan driver SDR may be disposed in a fourth non-display area NDA4 or both the third non-display area NDA3 and the fourth non-display area NDA4. The scan driver SDR may be connected to a signal connection line CWL. At least one end portion of the signal connection line CWL may form a pad WPD_CW on the first non-display area NDA1 and/or the second non-display area NDA2 and may be connected to an external device EXD.

The data line DTL and the reference voltage line RVL may extend in the second direction DR2 crossing the first direction DR1. A first supply voltage line ELVDL may include a portion extending in the second direction DR2. The first supply voltage line ELVDL may further include a portion extending in the first direction DR1. The first supply voltage line ELVDL may have, but is not limited to, a mesh structure.

The wire pads WPD may be disposed at an end portion of one or more of the data line DTL, the reference voltage line RVL, or the first supply voltage line ELVDL. Each of the wire pads WPD may be disposed in the pad area PDA of the non-display area NDA. According to an embodiment of the present disclosure, a wire pad WPD_DT of the data line DTL (hereinafter, referred to as a data pad) may be disposed in the pad area PDA of the first non-display area NDA1. A wire pad WPD_RV of the reference voltage line RVL (hereinafter referred to as a reference voltage pad) and a wire pad WPD_ELVD of the first supply voltage line ELVDL (hereinafter referred to as a first supply voltage pad) may be disposed in the pad area PDA of the second non-display area NDA2. As another example, the data pad WPD_DT, the reference voltage pad WPD_RV and the first supply voltage pad WPD_ELVD may each be disposed in a same area. e.g., the first non-display area NDA1. As described herein, the external device EXD may be mounted on the wire pads WPD. The external devices EXD may be mounted on the wire pads WPD by an anisotropic conductive film, ultrasonic bonding, etc.

FIG. 5 is an equivalent circuit diagram of a pixel of a display device according to an embodiment of the present disclosure.

Referring to FIG. 5, each of the pixels PX may include a pixel driver circuit. The lines may pass through each of the pixels PX or the periphery thereof to apply a driving signal to the pixel driving circuit. The pixel driving circuit may include transistors and a capacitor. The number of transistors and capacitors of each pixel driving circuit may be changed in a variety of ways. In the following example, the pixel driving circuit is described as having a 3TIC structure including three transistors and one capacitor. It is to be understood that the present disclosure is not limited thereto. A variety of modified pixel structures may be employed such as a 2TIC structure, a 7TIC structure or a 6TIC structure.

Each of the pixels PX of the display device according to an embodiment may include three transistors DTR, STR1 and STR2, a storage capacitor CST, and a light-emitting diode EMD.

The light-emitting diode EMD may emit light in proportion to a current supplied through a driving transistor DTR. The light-emitting diode EMD may be implemented as an organic light-emitting diode, a micro light-emitting diode, a nano light-emitting diode, etc.

The first electrode (e.g., the anode electrode) of the light-emitting diode EMD may be connected to the source electrode of the driving transistor DTR, and the second electrode (e.g., the cathode electrode) thereof may be connected to a second supply voltage line ELVSL, from which a low-level voltage (second supply voltage) may be applied. The low-level voltage of the second supply voltage line ELVSL may be lower than a high-level voltage (first supply voltage) of a first supply voltage line ELVDL.

The driving transistor DTR may adjust an electric current flowing from the first supply voltage line ELVDL from which the first supply voltage is applied to the light-emitting diode EMD according to the voltage difference between the gate electrode and the source electrode. The gate electrode of the driving transistor DTR may be connected to a source/drain electrode of the first switching transistor STR1, the source electrode may be connected to a first electrode of the light-emitting diode EMD, and the drain electrode may be connected to the first supply voltage line ELVDL from which the first supply voltage is applied.

The first switching transistor STR1 may be turned on by a scan signal of a scan line SCL to connect a data line DTL with the gate electrode of the driving transistor DTR. A gate electrode of the first switching transistor STR1 may be connected to the scan line SCL. A first source/drain electrode may be connected to the gate electrode of the driving transistor DTR and a second source/drain electrode may be connected to the data line DTL.

The second switching transistor STR2 may be turned on by a sensing signal of a sensing signal line SSL to connect a reference voltage line RVL to the source electrode of the driving transistor DTR. A gate electrode of the second switching transistor STR2 may be connected to the sensing signal line SSL, the first source/drain electrode thereof may be connected to the reference voltage line RVL, and the second source/drain electrode thereof may be connected to the source electrode of the driving transistor DTR.

According to an embodiment of the present disclosure, the first source/drain electrode of each of the first and second switching transistors STR1 and STR2 may be a source electrode while the second source/drain electrode thereof may be a drain electrode. It is to be understood that the present disclosure is not limited thereto. The first source/drain electrode of each of the first and second switching transistors STR1 and STR2 may be a drain electrode while the second source/drain electrode thereof may be a source electrode.

The capacitor CST may be formed between the gate electrode and the source electrode of the driving transistor DRT. The storage capacitor CST may store a voltage difference between the gate voltage and the source voltage of the driving transistor DTR.

The driving transistor DTR and the first and second switching transistors STR1 and STR2 may be formed as thin-film transistors. In addition, although FIG. 5 shows that each of the driving transistor DTR and the first and second switching transistors STR1 and STR2 may be implemented as an n-type MOSFET (metal oxide semiconductor field effect transistor), it is to be noted that the present disclosure is not limited thereto. That is to say, the driving transistor DTR and the first and second switching transistors STR1 and STR2 may be implemented as p-type MOSFETs, or some of them may be implemented as n-type MOSFETs while the others may be implemented as p-type MOSFETs.

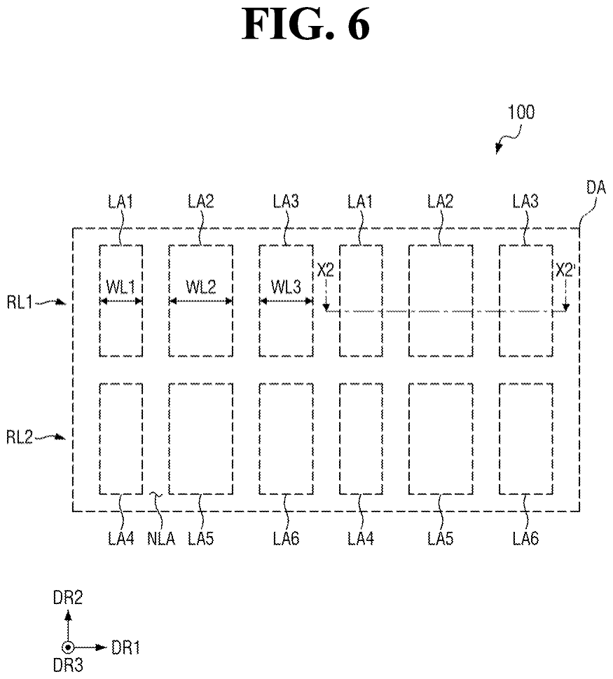

FIG. 6 is a plan view showing a display area of a display substrate in a display device according to an embodiment. FIG. 7 is a plan view showing a display area of a color conversion substrate in the display device according to an embodiment.

Referring to FIG. 6 and FIG. 7 in conjunction with FIG. 1 and FIG. 2, a plurality of light-emitting areas LA1, LA2, LA3, LA4, LA5 and LA6 and a non-light-emitting area NLA may be defined in the display area DA of the display substrate 100. In the light-emitting areas LA1, LA2, LA3, LA4, LA5 and LA6, light generated in the light-emitting elements of the display substrate 100 may exit out of the display substrate 100. In the non-light-emitting area NLA, no light may exit out of the display substrate 100.

According to an embodiment of the present disclosure, light emitted from the light-emitting areas LA1, LA2, LA3, LA4, LA5 and LA6 of the display substrate 100 to the color conversion substrate 200 may be light of the third color. According to an embodiment of the present disclosure, the third color light may be blue light and may have a peak wavelength in the range of about 440 nm to 480 nm. The peak wavelength may refer to the wavelength having a maximum intensity within a wavelength range.

According to an embodiment of the present disclosure, in a first row RL1 in the display area DA of the display substrate 100, a first light-emitting area LA1, a second light-emitting area LA2 and a third light-emitting area LA3 may be arranged repeatedly in order in the first direction DR1. In addition, in a second row RL2 adjacent to the first row RL1 in the second direction D2, a fourth light-emitting area LA4, a fifth light-emitting area LA5 and a sixth light-emitting area LA6 may be repeatedly arranged in order in the first direction DR1.

According to an embodiment, the first light-emitting area LA1 may have a predetermined first width WL1 in the first direction DR1, the second light-emitting area LA2 may have a predetermined second width WL2 in the first direction DR1, and the third light-emitting area LA3 may have a predetermined third width WL3 in the first direction DR1. The widths of the first light-emitting area LA1, the second light-emitting area LA2 and the third light-emitting area LA3 may be the same or different. In an example, the first width WL1 of the first light-emitting area LA1 may be smaller than the second width WL2 of the second light-emitting area LA2 and the third width WL3 of the third light-emitting area LA3. According to an embodiment of the present disclosure, the second width WL2 of the second light-emitting area LA2 may be different than the third width WL3 of the third light-emitting area LA3. In an example, the second width WL2 of the second light-emitting area LA2 may be greater than the third width WL3 of the third light-emitting area LA3. In addition, according to an embodiment of the present disclosure, the areas of the first light-emitting area LA1, the second light-emitting area LA2 and the third light-emitting area LA3 may be the same or different. In an example, the area of the first light-emitting area LA1 may be smaller than the area of the second light-emitting area LA2 and the area of the third light-emitting area LA3. The second light-emitting area LA2 may be larger than the third light-emitting area LA3. It should be understood that the present disclosure is not limited thereto. For example, the second light-emitting area LA2 may be smaller than the third light-emitting area LA3.

According to an embodiment, the first width WL1 of the first light-emitting area LA1, the second width WL2 of the second light-emitting area LA2 and the third width WL3 of the third light-emitting area LA3 may be all equal. According to an embodiment, the first light-emitting area LA1, the second light-emitting area LA2 and the third light-emitting area LA3 may have substantially the same area.

The width, area, and structure of the elements of the fourth light-emitting area LA4 adjacent to the first light-emitting area LA1 in the second direction DR2 are substantially the same as those of the first light-emitting area LA1, except that the fourth light-emitting area LA3 may be located in the second row RD2. Similarly, the fifth light-emitting area LA5 adjacent to the second light-emitting area LA2 in the second direction DR2 may have substantially the same structure as that of the second light-emitting area LA2, and the sixth light-emitting area LA6 adjacent to the third light-emitting area LA3 in the second direction DR2 may have substantially the same structure as that of the third light-emitting area LA3.

A plurality of light-transmitting areas TA1, TA2, TA3, TA4, TA5 and TA6 and a light-blocking area BA may be defined in the display area DA of the color conversion substrate 200. In the light-transmitting areas TA1, TA2, TA3, TA4, TA5 and TA6, the light exiting from the display substrate 100 may transit the color conversion substrate 200 to be provided to the outside of the display device 1. The light exiting from the display substrate 100 may not pass through the light-blocking area BA.

According to an embodiment of the present disclosure, in a first row RT1 in the display area DA of the color conversion substrate 200, a first light-transmitting area TA1, a second light-transmitting area TA2 and a third light-transmitting area TA3 may be arranged repeatedly in order in the first direction DR1. The first light-transmitting area TA1 may have the size equal to the size of the first light-emitting area LA1 or may overlap with the first light-emitting area LA1. Similarly, the second light-transmitting area TA2 may have the size equal to the size of the second emission area LA2 or may overlap the second emission area LA2, and the third light-transmitting area TA3 may have the size equal to the size of the third emission area LA3 or may overlap the third emission area LA3.

According to an embodiment of the present disclosure, the light of the third color provided from the display substrate 100 may pass through the first light-transmitting area TA1, the second light-transmitting area TA2 and the third light-transmitting area TA3 and may exit out of the display device 1. Light exiting from the first light-transmitting area TA1 to the outside of the display device 1 may be referred to as a third exit light. Light exiting from the second light-transmitting area TA2 to the outside of the display device 1 may be referred to as a second exit light. Light exiting from the third light-transmitting area TA3 to the outside of the display device 1 may be referred to as a first exit light. The third exit light may be light of the third color, the second exit light may be light of the third color, and the first exit light may be light of the first color. According to an embodiment, the light of the third color may be blue light having a peak wavelength in the range of about 440 nm to 480 nm, and the light of the second color may be green light having a peak wavelength in the range of about 510 nm to 550 nm. In addition, the light of the first color may be red light having a peak wavelength in the range of about 610 to 650 nm. It should be understood that the present disclosure is not limited thereto. For example, the light of the second color may be red light and the light of the first color may be green light.

In a second row RT2 adjacent to the first row RR1 in the second direction DR2, the fourth light-transmitting area TA4, the fifth light-transmitting area TA5 and the sixth light-transmitting area TA6 may be repeatedly arranged in order in the first direction DR1. The fourth light-transmitting area TA4 may be in line with or overlap with the fourth light-emitting area LA4, and the fifth light-transmitting area TA5 may be in line with or overlap with the fifth light-emitting area LA5, and the sixth light-transmitting area TA6 may be in line with or overlap with the sixth light-emitting area LA6.

According to an embodiment, the first light-transmitting area TA1 may have a predetermined first width WT1 in the first direction DR1, the second light-transmitting area TA2 may have a predetermined second width WT2 in the first direction DR1, and the third light-transmitting area TA3 may have a predetermined third width WT3 in the first direction DR1. The widths of the first light-transmitting area TA1, the second light-transmitting area TA2, and the third light-transmitting area TA3 may be the same or different. In an example, the first width WT1 of the first light-transmitting area TA1 may be equal to the second width WT2 of the second light-transmitting area TA2 and the third width WT3 of the third light-transmitting area TA3. According to an embodiment of the present disclosure, the second width WT2 of the second light-transmitting area TA2 may be different from the third width WT3 of the third light-transmitting area TA3. The second width WT2 of the second light-transmitting area TA2 may be greater than or smaller than the third width WT3 of the third light-transmitting area TA3. In addition, according to an embodiment of the present disclosure, the first light-transmitting area TA1 may be smaller than the second light-transmitting area TA2 and the third light-transmitting area TA3, and may be greater than the second light-transmitting area TA2 and the third light-transmitting area TA3.

It is to be understood that the present disclosure is not limited thereto. According to an embodiment, the first width WT1 of the first light-transmitting area TA1, the second width WT2 of the second light-transmitting area TA2 and the third width WT3 of the third light-transmitting area TA3 may be substantially equal. According to an embodiment, the area of the first light-transmitting area TA1 may be substantially equal to the area of the second light-transmitting area TA2 and the area of the third light-transmitting area TA3.

The first light-transmitting area TA1 and the fourth light-transmitting area TA4, which may be adjacent to each other in the second direction DR2, may have substantially the same width and area, and the same elements disposed therein, and a color of the light exiting out of the display device 1. Similarly, the second light-transmitting area TA2 and the fifth light-transmitting area TA5, which may be adjacent to each other in the second direction DR2, may have substantially the same structure and the same color of the light exiting out of the display device 1. In addition, the third light-transmitting area TA3 and the sixth light-transmitting area TA6, which are adjacent to each other in the second direction DR2, may have substantially the same structure and the same color of the light exiting out of the display device 1.

The light-blocking area BA may be located around the light-transmitting areas TA1, TA2, TA3. TA4, TA5 and TA6 of the color conversion substrate 200 in the display area DA. According to an embodiment of the present disclosure, the light-blocking area BA may be divided into a first light-blocking area BA1, a second light-blocking area BA2, a third light-blocking area BA3, a fourth light-blocking area BA4, a fifth light-blocking area BA5, a sixth light-blocking area BA6, and a seventh light-blocking area BA7.

The first light-blocking area BA1 may be located between the first light-transmitting area TA1 and the second light-transmitting area TA2. The second light-blocking area BA2 may be located between the second light-transmitting area TA2 and the third light-transmitting area TA3. The third light-blocking area BA3 may be located between the third light-transmitting area TA3 and another first light-transmitting area TA1 adjacent to the third light-transmitting area TA3.

The fourth light-blocking area BA4 may be located between the fourth light-transmitting area TA4 and the fifth light-transmitting area TA5. The fifth light-blocking area BA5 may be located between the fifth light-transmitting area TA5 and the sixth light-transmitting area TA6. The sixth light-blocking area BA6 may be located between the sixth light-transmitting area TA6 and another fourth light-transmitting area TA4 adjacent to the sixth light-transmitting area TA6.

The seventh light-blocking area BA7 may be located between the first row RT1 and the second row RT2 adjacent to each other in the second direction DR2.

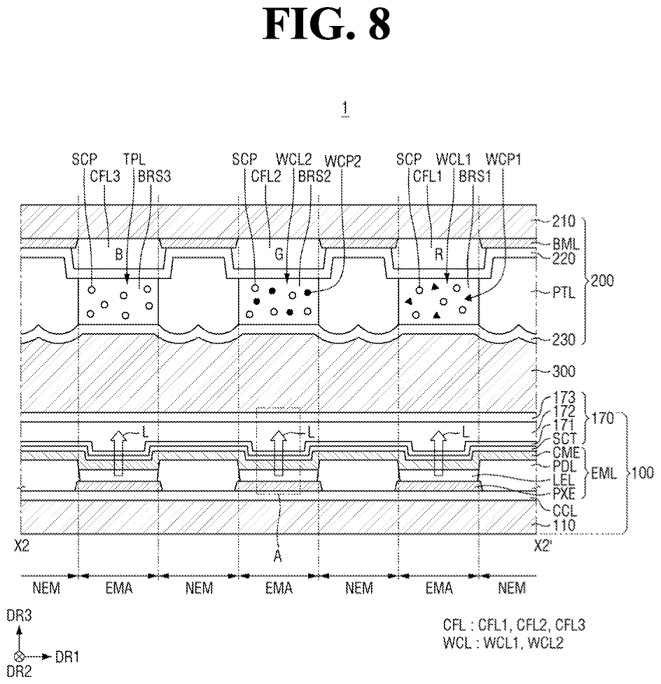

FIG. 8 is a cross-sectional view of the display device, taken along line X2-X2′ of FIG. 7.

Referring to FIG. 8, the display device 1 may include the display substrate 100, the color conversion substrate 200 facing the display substrate 100, and the filler 300 attaching the display substrate 100 and the color conversion substrate 200 together.

The display substrate 100 may include a first substrate 110, a circuit layer CCL, an emission material layer EML, and an encapsulation structure 170.

The first substrate 110 may include a transparent material. For example, the first substrate 110 may include a transparent insulating material such as glass and quartz. The first substrate 110 may be a rigid substrate. The first substrate 110 is not limited to those described herein. The first substrate 110 may include a plastic such as polyimide or may be flexible so that it can be curved, bent, folded, or rolled.

The circuit layer CCL may be disposed on the first substrate 110. The circuit layer CCL are described with reference to FIG. 4; and, therefore, the redundant descriptions may be omitted.

The emission material layer EML may be disposed on the circuit layer CCL. The emission material layer EML may include a pixel electrode PXE, a pixel-defining film PDL, a light-emitting layer LEL, and a common electrode CME.

The pixel electrode PXE may be a first electrode, e.g., an anode electrode of a light-emitting diode. The pixel electrode PXE may have a stack structure of a material layer having a high work function such as indium-tin-oxide (ITO), indium-zinc-oxide (IZO), zinc oxide (ZnO) or indium oxide (In₂O₃), and a reflective material layer such as silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca) or a mixture thereof. A material layer having a higher work function may be disposed on a higher layer than a reflective material layer, which may be closer to the light-emitting layer LEL. The pixel electrode PXE may have, but is not limited to, a multilayer structure of ITO/Mg. ITO/MgF. ITO/Ag, or ITO/Ag/ITO.

The pixel-defining layer PDL may be disposed on a surface of the first substrate 110 along the boundaries of the pixels PX. The pixel-defining layer PDL may be disposed over the pixel electrode PXE. The pixel-defining layer PDL may include an opening exposing the pixel electrodes PXE. The emission areas EMA and the non-emission area NEM may be distinguished by the pixel-defining layer PDL and the opening thereof. The pixel-defining film PDL may include an organic insulating material such as polyacrylate resin, epoxy resin, phenolic resin, polyamide resin, polyimide resin, unsaturated polyesters resin, poly phenylen ether resin, poly phenylene sulfide resin, or benzocyclobutene (BCB). The pixel-defining layer PDL may include an inorganic material.

The light-emitting layer LEL may be disposed on the pixel electrode PXE exposed by the pixel-defining film PDL. According to an embodiment where the display device 1 is an organic light-emitting display device, the light-emitting layer LEL may include an organic layer containing an organic material. The organic layer may include an organic, emissive layer and may further include at least one of a hole injection layer, a hole transport layer, an electron injection layer or an electronic transport layer as an auxiliary layer in some implementations, which may facilitate emission. In an embodiment where the display device 1 is a micro LED display device, a nano LED display device, etc., the light-emitting layer LEL may include an inorganic material such as an inorganic semiconductor.

In some embodiments, the light-emitting layer LEL may have a tandem structure including a plurality of organic emissive layers overlapping one another in the thickness direction and a charge generation layer disposed therebetween. The organic emissive layers overlapping one another may emit either light of the same wavelength or light of different wavelengths. At least some layers of the light-emitting layer LEL of each pixel PX may be separated from the counterpart layers of the adjacent pixel PX.

According to an embodiment of the present disclosure, the light-emitting layers LEL of the different color pixels PX may emit light of the same wavelength. For example, the light-emitting layer LEL of each color pixel PX may emit blue light or ultraviolet light, and a color control structure may include a wavelength conversion layer WCL, so that different pixels PX may display light of different colors.

According to an embodiment of the present disclosure, the light-emitting layers LEL of different color pixels PX may emit light of different wavelengths. For example, the light-emitting layer LEL of a first color pixel PX may emit light of a first color, the light-emitting layer LEL of a second color pixel PX may emit light of a second color, and the light-emitting layer LEL of a third color pixel PX may emit light of a third color.

The common electrode CME may be disposed on the light-emitting layer LEL. The common electrode CME may be in contact with the light-emitting layer LEL and the upper surface of the pixel-defining film PDL. The common electrode CME may extend across the pixels PX. The common electrode CME may be disposed on the entire surface across the pixels PX. The common electrode CME may be a second electrode, i.e., a cathode electrode of the light-emitting diode. The common electrode CME may include a material layer having a small work function such as Li, Ca, LiF/Ca, LiF/Al, Al, Mg. Ag. Pt, Pd, Ni, Au, Nd, Ir, Cr, BaF or Ba, or a compound or mixture thereof (e.g., a mixture of Ag and Mg). The common electrode CME may further include a transparent metal oxide layer disposed on the material layer having a small work function.

The pixel electrode PXE, the light-emitting layer LEL and the common electrode CME may form a light-emitting element (e.g., an organic light-emitting element). Light emitted from the light-emitting layer LEL may pass through the common electrode CME to exit upwardly.

The encapsulation structure 170 may be disposed on the common electrode CME. The encapsulation structure 170 may include at least one thin-film encapsulation layer or a scattering layer SCT. For example, the encapsulation structure 170 may include the scattering layer SCT, a first inorganic film 171, a first organic film 172 and a second inorganic film 173.

The first inorganic film 171 may be disposed on the emission material layer EML. The first inorganic film 171 may be disposed on the scattering layer SCT. The first inorganic film 171 may be disposed directly on the scattering layer SCT. The first inorganic film 171 may include silicon nitride (SiNx), silicon oxide (SiOx), or silicon oxynitride (SiOxNy). The thickness of the first inorganic film 171 may range from about 0.7 μm to 1 μm.

The first organic film 172 may be disposed on the first inorganic film 171. The first organic film 172 may include an organic insulating material such as polyacrylate resin, epoxy resin, phenolic resin, polyamide resin, polyimide resin, unsaturated polyesters resin, polyphenylene ether resin, polyphenylene sulfide resin, or benzocyclobutene (BCB). The thickness of the first organic film 172 may range from about 2 μm to 5 μm.

The second inorganic film 173 may be disposed on the first organic film 172. The second inorganic film 173 may contain the same material as the first inorganic film 171 described herein. For example, the second inorganic film 173 may include silicon nitride (SiNx), silicon oxide (SiOx), or silicon oxynitride (SiOxNy). The thickness of the second inorganic film 173 may range from about 0.7 μm to 1.0 μm.

The scattering layer SCT may be disposed under the first inorganic film 171. The scattering layer SCT may be disposed on the emission material layer EML. For example, the scattering layer SCT may be disposed between the first inorganic film 171 and the common electrode CME of the emission material layer EML.

The scattering layer SCT may at least partially include the same material as the first inorganic film 171. For example, the scattering layer SCT may at least partially include a material such as silicon nitride (SiNx), silicon oxide (SiOx), or silicon oxynitride (SiOxNy).

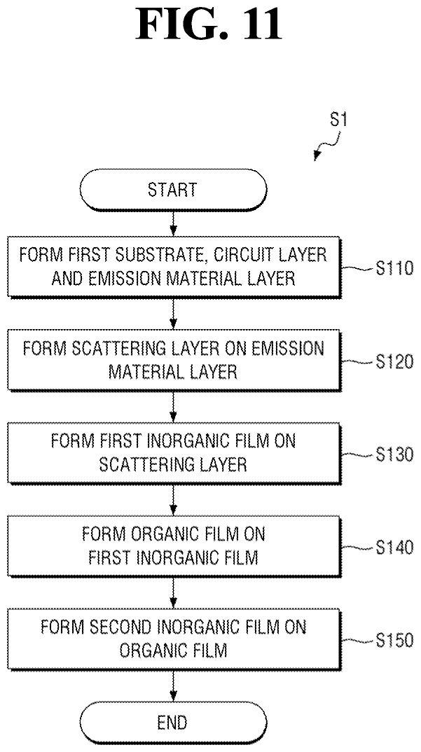

In some embodiments, the scattering layer SCT may further include at least one of silane (SiH₄), nitrous oxide (N₂O), or ammonia (NH₃). Materials such as silane (SiH₄), nitrous oxide (N₂O) or ammonia (NH₃) of the scattering layer SCT may be formed by a method (S1) of fabricating a display device according to an embodiment (see FIG. 11).

The color conversion substrate 200 may be disposed on the encapsulation structure 170 to face it. The color conversion substrate 200 may include a second substrate 210, a light-blocking member BML, a color filter layer CFL, a first capping layer 220, partition walls PTL, a wavelength conversion layer WCL, a transparent layer TPL, and a second capping layer 230.

The second substrate 210 may include a transparent material. The second substrate 210 may include a transparent insulating material such as glass or quartz. The second substrate 210 may be a rigid substrate. The second substrate 210 is not limited thereto. In an example, the second substrate 210 may include a plastic such as polyimide or may be flexible so that it can be curved, bent, folded, or rolled.

The second substrate 210 may be of the same type as the first substrate 110 or may have different material, thickness, transmittance, etc. For example, the second substrate 210 may have a higher transmittance than the first substrate 110. The second substrate 210 may be either thicker or thinner than the first substrate 110.

The light-blocking member BML may be disposed along the boundary of the pixels PX on a surface of the second substrate 210 facing the first substrate 110. The light-blocking member BM may overlap with the pixel-defining film PDL of the display substrate 100 and may be disposed in the non-emission area NEM. The light-blocking member BML may include openings exposing a surface of the second substrate 210 overlapping the emission areas EMA. The light-blocking member BML may be formed in a lattice shape when viewed from the top.

The light-blocking member BML may include an organic material. The light-blocking member BML may absorb external light, and may thereby reduce color distortion due to reflection of external light. In addition, the light-blocking member BML can reduce or prevent light emitted from the light-emitting layer LEL from intruding into adjacent pixels PX.

According to an embodiment of the present disclosure, the light-blocking member BML can absorb visible wavelengths. In an example, the light-blocking member BML may absorb all visible wavelengths. The light-blocking member BML may include a light-absorbing material. For example, the light-blocking member BML may be made of a material used as a black matrix of the display device 1.

According to an embodiment, the light-blocking member BML may absorb light in a particular wavelength range among the visible light wavelengths and may allow light in other wavelength ranges to pass through. For example, the light-blocking member BML may include the same material as the color filter layers CFL. Specifically, the light-blocking member BMK may be made of the same material as a blue color filter layer. In some embodiments, the light-blocking member BML may be formed integrally with the blue color filter layer. In addition, the light-blocking member BML may be omitted.

The color filter layers CFL may be disposed on the surface of the second substrate 210 where the light-blocking member BML may be disposed. The color filter layers CFL may be disposed on the surface of the second substrate 210 exposed through the opening of the light-blocking member BML. Furthermore, the color filter layers CFL may be partially disposed on the adjacent light-blocking member BML.

The color filter layer CFL may include a first color filter layer CFL1 disposed in the first color pixel PX, a second color filter layer CFL2 disposed in the second color pixel PX, and a third color filter layer CFL3 disposed in the third color pixel PX. Each of the color filter layers CFL may include a colorant, such as a dye and a pigment, which may absorb wavelengths other than the wavelength of the color it represents. The first color filter layer CFL1 may be a red color filter layer, the second color filter layer CFL2 may be a green color filter layer, and the third color filter layer CFL3 may be a blue color filter layer. Although the adjacent color filters CFL may be spaced apart from one another on the light-blocking member BML in the example shown in the drawings, the present disclosure is not limited thereto. The adjacent color filter layers CFL may partially overlap one another on the light-blocking member BML.

The first capping layer 220 may be disposed on the color filter layer CFL. The first capping layer 220 can reduce or prevent impurities such as moisture and air from permeating from the outside to damage or contaminate the color filter layer CFL. In addition, the first capping layer 220 can reduce or prevent the colorant of the color filter layer CFL from being diffused into other elements.

The first capping layer 220 may be in direct contact with a surface (lower surface in FIG. 8) of the color filter layers CFL. The first capping layer 220 may be made of an inorganic material. For example, the first capping layer 220 may be made of a material including silicon nitride, aluminum nitride, zirconium nitride, titanium nitride, hafnium nitride, tantalum nitride, silicon oxide, aluminum oxide, titanium oxide, tin oxide, silicon oxynitride, etc.

The partition walls PTL may be disposed on the first capping layer 220. The partition walls PTL may be disposed in the non-emission area NEM. The partition walls PTL may be disposed such that they overlap with the light-blocking member BML. The partition walls PTL may include openings through which the color filter layers CFL may be exposed. The partition walls PTL may include, but are not limited to, a photosensitive organic material. The partition walls PTL may further include a light-blocking material.

The wavelength conversion layer WCL and/or the transparent layer TPL may be disposed in the space exposed by the openings of the partition walls PTL. The wavelength conversion layer WCL and the transparent layer TPL may be formed by, but are not limited to, an inkjet process using the partition walls PTL as a bank.

According to an embodiment where the light-emitting layer LEL of each of the pixels PX emit light of a third color, the wavelength conversion layer WCL may include a first wavelength conversion pattern WCL1 disposed in the first color pixel PX, and a second wavelength conversion pattern WCL2 disposed in the second color pixel PX. The transparent layer TPL may be disposed in the third color pixel PX.

The first wavelength conversion pattern WCL1 may include a first base resin BRS1, and first wavelength-converting particles WCP1 dispersed in the first base resin BRS1. The second wavelength conversion pattern WCL2 may include a second base resin BRS2 and second wavelength-converting particles WCP2 dispersed in the second base resin BRS2. The transparent layer TPL may include a third base resin BRS3 and scatterers SCP dispersed therein.

The first to third base resins BRS1, BRS2 and BRS3 may include a transparent organic material. For example, the first to third base resins BRS1, BRS2 and BRS3 may include an epoxy resin, an acrylic resin, a cardo resin, an imide resin, or the like. The first to third base resins BRS1, BRS2 and BRS3 may be made of, but are not limited to, the same material.

The scattering particles SCP may be metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), etc. Examples of the material of the organic particles may include an acrylic resin, a urethane resin, etc.

The first wavelength-converting particles WCP1 may convert the third color into the first color, and the second wavelength-converting particles WCP2 may convert the third color into the second color. The first wavelength-converting particles WCP1 and the second wavelength-converting particles WCP2 may be quantum dots, quantum rods, phosphors, etc. The quantum dots may include IV nanocrystals, II-VI compound nanocrystals, III-V compound nanocrystals, IV-VI nanocrystals, or combinations thereof. The first wavelength conversion pattern WCL1 and the second wavelength conversion pattern WCL2 may further include scattering particles SCP that may increase wavelength conversion efficiency.

The transparent layer TPL disposed in the third color pixel PX may allow the light of the third color to pass and be emitted from the light-emitting layer LEL without changing the wavelength. The scattering particles SCP of the transparent layer TPL may adjust a path of exiting light through the transparent layer TPL. The transparent layer TPL may include no wavelength conversion material.

The second capping layer 230 may be disposed on the wavelength conversion layer WCL, the transparent layer TPL and the partition walls PTL. The second capping layer 230 may be made of an inorganic material. The second capping layer 230 may include a material selected from among the materials listed herein as materials of the first capping layer 220. The second capping layer 230 and the first capping layer 220 may be made of, but are not limited to, the same material.

The filler 300 may be disposed between the display substrate 100 and the color conversion substrate 200. The filler 300 may fill the space between the display substrate 100 and the color conversion substrate 200 and may to adhere and couple the display substrate 100 and the color conversion substrate 200 together. The filler 300 may be disposed between the encapsulation structure 170 of the display substrate 100 and the second capping layer 230 of the color conversion substrate 200. The filler 300 may be made of, but is not limited to, a Si-based organic material, an epoxy-based organic material, etc.

Hereinafter, the encapsulation structure will be described in more detail.

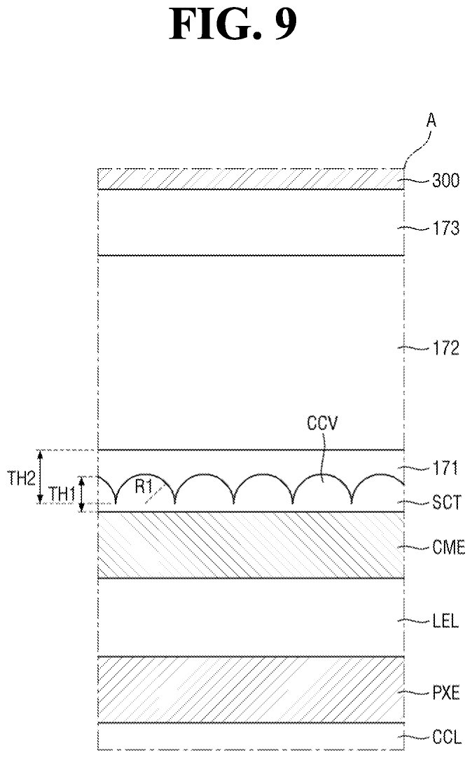

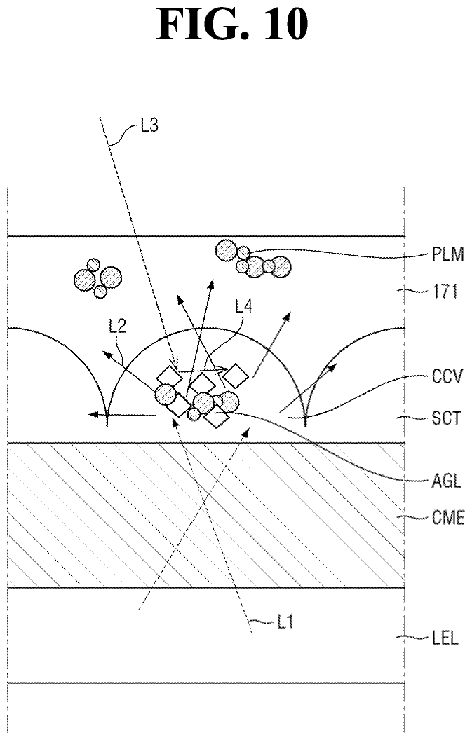

FIG. 9 is an enlarged view of portion A of FIG. 8. FIG. 10 is a cross-sectional view illustrating a state in which light may be scattered by a scattering layer according to an embodiment.

Referring to FIG. 9 and FIG. 10, the scattering layer SCT may include a plurality of convex portions CCV. A plurality of concave portions CCV may be disposed on the upper surface of the scattering layer SCT. The convex portions CCV may be arranged in the first and second directions DR1 and DR2. Although adjacent ones of the plurality of convex portions CCV may be in direct contact with each other in the example shown in the drawings, the present disclosure is not limited thereto. For example, the plurality of convex portions CCV may be arranged at a constant distance or may be arranged at different distances in the first and second directions DR1 and DR2. Alternatively, some of the convex portions CCV may be in direct contact with each other, and the other convex portions CCV may be spaced apart from each other.

The convex portions CCV may have a hemispherical shape. For example, as shown in the drawings, upper surfaces of the convex portions CCV may have an arc shape on the cross section cut along the third direction DR3.

Although the convex portions CCV have the same size in the drawings, the present disclosure is not limited thereto. The convex portions CCV may have different sizes. The average radius R1 of the convex portions CCV may range from about 0.15 μm to 0.25 μm. The average radius may refer to the average value of the radii of the convex portions CCV. The convex portions CCV may be formed in a hemispherical shape, which may be a stable form, by attraction between particles acting in different directions.

The thickness TH1 of the scattering layer SCT may range from about 0.3 to 0.75 times the thickness TH2 of the first inorganic film 171. For example, the thickness TH1 of the scattering layer SCT may range from about 0.3 μm to 0.5 μm.

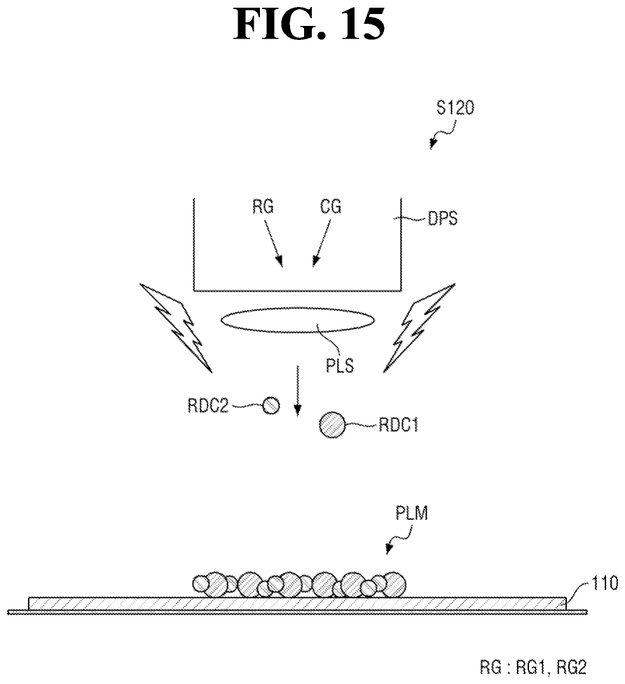

Referring to FIG. 10, the first inorganic film 171 may include a polymer PLM (e.g., first particles). The polymer PLM may be particles made of a material such as silicon nitride (SiNx), silicon oxide (SiOx) or silicon oxynitride (SiOxNy). The polymer PLM may be particles formed by polymerization of completely ionized radicals RDC1 and RDC2 (see FIG. 15) in a method S1 of fabricating a display device (see FIG. 11).

The scattering layer SCT may include aggregated scattering particles AGL (e.g., second particles). For example, the scattering layer SCT may include the polymer PLM included in the first inorganic film 171 and the scattering particles AGL not included in the first inorganic film 171. The scattering particles AGL may be larger than the polymer PLM. The scattering particles AGL may include at least one of silane (SiH₄), nitrous oxide (N₂O), or ammonia (NH₃). The scattering particles AGL may be formed as the polymer PLM formed by polymerizing completely ionized radicals RDC1 and RDC2 (see FIG. 15) and fragmented precursors FRG (see FIG. 15) that are not completely ionized are aggregated in the method S1 (see FIG. 11) described herein. The fragmented precursors FRG (see FIG. 15) may include at least one of silane (SiH₄), nitrous oxide (N₂O), or ammonia (NH₃).

According to an embodiment, the display device 1 may include the scattering particles AGL, and the scattering layer SCT may work as a guide film. For example, a light L1 emitted from the light-emitting layer LEL may transit the common electrode CME and the scattering layer SCT before reaching the first inorganic film 171. In doing so, light L2 may be refracted and scattered in various directions by the scattering particles AGL included in the scattering layer SCT. Accordingly, the amount of the refracted and scattered light L2 that reaches the color conversion elements included in the color conversion substrate 200 can be increased. As described herein, the color conversion substrate 200 may include the first wavelength conversion pattern WCL1, the second wavelength conversion pattern WCL2, and the transparent layer TPL can be increased. As a result, the luminous efficiency of the display device 1 can be improved.

According to an embodiment, the display device 1 includes the scattering particles AGL, and the scattering layer SCT may work as an antireflective film. For example, light L3 incident from the outside on the display surface of the display device may be refracted and scattered in various directions by the scattering particles AGL of the scattering layer SCT. Such scattered light L4 may not be reflected back to the outside through the display surface but may be absorbed inside the scattering layer SCT or inside the display device 1, or may not be recognized from the outside because the luminance of the light may be weakened.

Table 1 shows the external light reflectance of a conventional display device without the scattering layer SCT and the external light reflectance of the display device 1 according to an embodiment including the scattering layer SCT. In Table 1, external light reflectance values are provided in a specular component included (SCI) mode and a specular component excluded (SCE) mode.

TABLE 1

| | SCI | SCE |
|---|---|---|
| Conventional Display Device | 1.09 | 0.61 |
| Display Device | 1.03 | 0.58 |

The existing display device has the reflectance value of 1.09 in the SCI mode and the reflectance value of 0.61 in the SCE mode. In contrast, the display device 1 according to an embodiment has the reflectance value of 1.03 in the SCI mode and the reflectance value of 0.58 in the SCE mode.

Lower reflectance values in the SCI mode and the SCE mode imply less external light being reflected in the display device 1 and viewed from the outside. Accordingly, it can be seen that the display device 1 according to an embodiment can reduce or prevent reflection of external light, and is an improved display device.

Hereinafter, a method of fabricating a display device according to an embodiment of the present disclosure will be described.

FIG. 11 is a flowchart for illustrating a method of fabricating a display device according to an embodiment of the present disclosure.

Referring to FIG. 11 in conjunction with FIG. 8, a method of fabricating a display device according to an embodiment (S1) may include forming a first substrate, a circuit layer and an emission material layer (step S110); forming a scattering layer on the emission material layer (step S120); forming a first inorganic film on the scattering layer (step S130); forming an organic film on the first inorganic film (step S140); and forming a second inorganic film on the organic film (step S150).

In the forming S100 of the first substrate, the circuit layer and the emission material layer, the circuit layer CCL may be formed on the first substrate 110, and the emission material layer EML may be formed on the circuit layer CCL. The circuit layer CCL and the emission material layer EML may be formed by various processes such as a photolithography process and a deposition process depending on a structure to be formed.

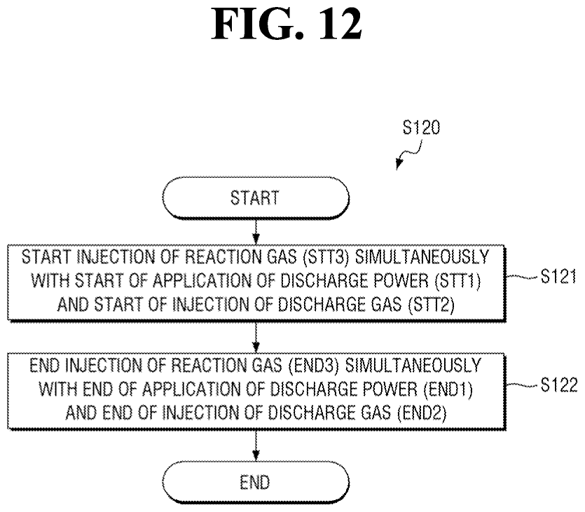

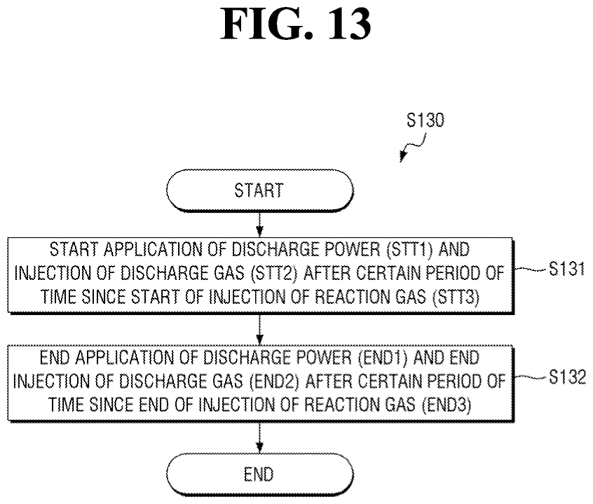

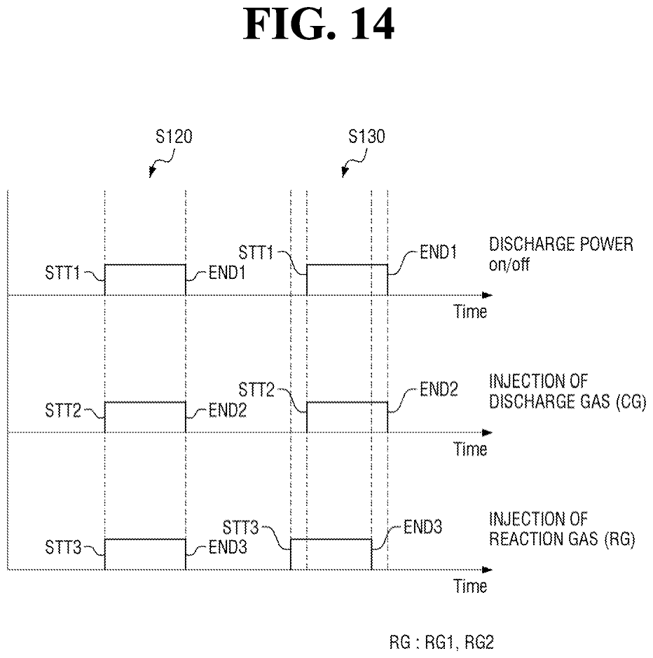

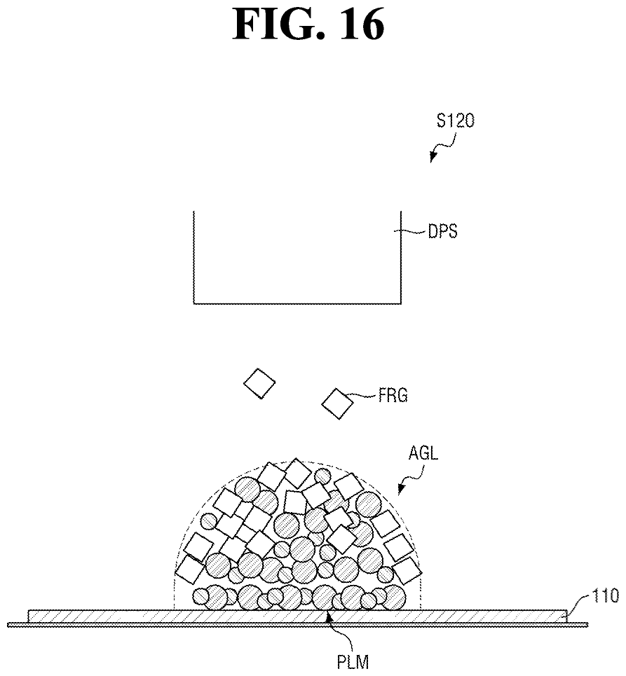

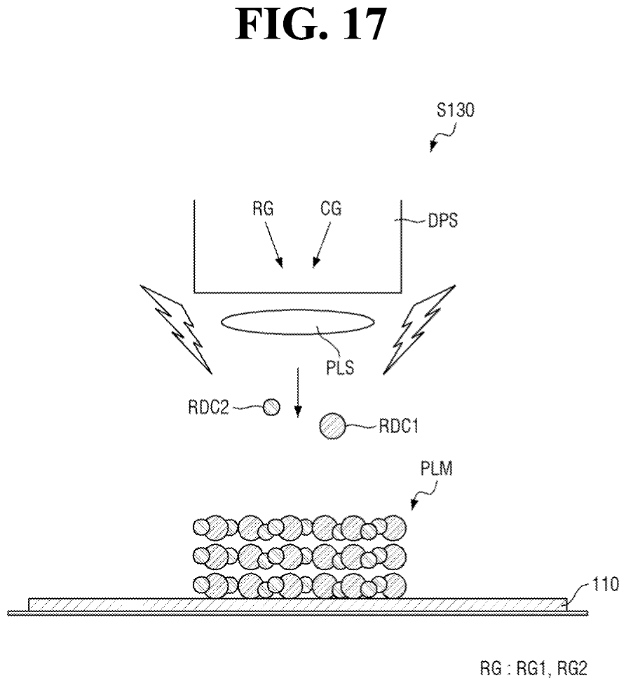

In the forming S120 of the scattering layer on the emission material layer, the scattering layer SCT may be formed on the emission material layer EML. The scattering layer SCT may include at least one of silane (SiH₄), nitrous oxide (N₂O) or ammonia (NH₃) or a material such as silicon nitride (SiNx), silicon oxide (SiOx) or silicon oxynitride (SiOxNy). The forming S120 of the scattering layer on the emission material layer is described with reference to FIG. 12, FIG. 13, FIG. 14, FIG. 15, FIG. 16, and FIG. 17.

In the forming S130 of the first inorganic film on the scattering layer, the first inorganic film 171 may be formed on the scattering layer SCT. The first inorganic film 171 may include silicon nitride (SiNx), silicon oxide (SiOx), or silicon oxynitride (SiOxNy). The forming S130 of the first inorganic film on the scattering layer is described with reference to FIGS. 12 to 17 together with the forming S120 of the scattering layer on the emission material layer.

In the forming S140 of the organic film on the first inorganic film, the first organic film 172 may be formed on the first inorganic film 171. The first organic film 172 may include an organic insulating material such as polyacrylate resin, epoxy resin, phenolic resin, polyamide resin, polyimide resin, unsaturated polyesters resin, polyphenylene ether resin, polyphenylene sulfide resin, or benzocyclobutene (BCB). The first organic film 172 may be formed by directly applying different materials or by curing a monomer using heat or ultraviolet light.

In the forming S150 of the second inorganic film on the organic film, the second inorganic film 173 may be formed on the first organic film 172. The second inorganic film 173 may be made of the same material via the same process as the first inorganic film 171; and, therefore, the redundant descriptions may be omitted.

FIG. 12 is a flowchart for illustrating step S120 according to an embodiment of the present disclosure. FIG. 13 is a flowchart for illustrating step S130 according to an embodiment of the present disclosure. FIG. 14 is a view for conceptually illustrating steps S120 and S130 according to an embodiment of the present disclosure. FIG. 15 is a cross-sectional view for illustrating step S120 according to an embodiment of the present disclosure. FIG. 16 is a cross-sectional view for illustrating step S120 according to an embodiment of the present disclosure. FIG. 17 is a cross-sectional view for illustrating step S130 according to an embodiment of the present disclosure.

Referring to FIG. 12, the forming S120 of the scattering layer on the emission material layer may include starting the injection of a reaction gas STT3 at about a same time as the start of the application of discharge power STT1 and the start of the injection of discharge gas STT2 (step S121), and ending the injection of the reaction gas END3 at about a same time as the end of the application of the discharge power END1 and the end of the injection of the discharge gas END2 (step S122). The forming S120 of the scattering layer on the emission material layer may include starting the injection of a reaction gas STT3 simultaneously with the start of the application of discharge power STT1 and the start of the injection of discharge gas STT2 (step S121). The injection of the reaction gas END3 may be ended simultaneously with the end of the application of the discharge power END1 and the end of the injection of the discharge gas END2 (step S122).

Referring to FIG. 13, the forming S130 of the first inorganic film on the scattering layer may include starting the application of the discharge power STT1 and the injection of discharge gas STT2 after a certain period of time from the starting of the injection of the reaction gas STT3 (step S131), and ending the application of the discharge power END1 and the injection of the discharge gas END2 after a certain period of time from the ending the injection of the reaction gas END3 (step S132).

Referring to FIGS. 12 to 17 in conjunction with FIG. 9, the scattering layer SCT, the first inorganic film 171 and the second inorganic film 173 may be formed via a chemical vapor deposition (CVD) process and/or a plasma enhanced chemical vapor deposition (PECVD) process. Herein, for convenience of illustration, the scattering layer SCT, the first inorganic film 171 and the second inorganic film 173 are described as being formed by a plasma chemical vapor deposition process as an example.

A deposition apparatus DPS may supply the reaction gas RG and the discharge gas CG into a chamber (not shown). The reaction gas RG may include a plurality of reaction gases. In an example, the reaction gas RG may include a first reaction gas RG1 and a second reaction gas RG2. For example, the first reaction gas RG1 may include a silane (SiH₄) gas as a source gas.

According to an embodiment in which the first inorganic film 171 and the second inorganic film 173 include silicon oxide (SiOx), the second reaction gas RG2 may be nitrous oxide (N₂O) gas. According to an embodiment in which the first inorganic film 171 and the second inorganic film 173 include silicon nitride (SiNx), the second reaction gas RG2 may be nitrous ammonia (NH₃). According to an embodiment, when the first inorganic film 171 and the second inorganic film 173 include both silicon oxide (SiOx) and silicon nitride (SiNx), the second reaction gas RG2 may be a mixed gas of nitrous oxide (N₂O) and ammonia (NH₃).

The discharge gas CG may be an inert gas such as oxygen (O₂), nitrogen (N₂), argon (Ar), or helium (He) gas. In some embodiments, oxygen (O₂) gas may be used when the first inorganic film 171 and the second inorganic film 173 include silicon oxide (SiOx), and nitrogen (N₂) gas may be used when the first inorganic film 171 and the second inorganic film 173 include silicon nitride (SiNx). It is to be understood that the present disclosure is not limited thereto. In an example, the discharge gas CG may be supplied together with the discharge power to form plasma PLS.

When the reaction gas RG and the discharge gas CG are supplied and the discharge power is applied, the plasma PLS may be formed between the deposition apparatus DPS and the first substrate 110. Once the plasma PLS is formed, the reaction gases RG may be dissociated into completely ionized radicals RDC1 and RDC2. The first radicals RDC1 may be generated by dissociation of the first reaction gas RG1, and the second radicals RDC2 may be generated by dissociation of the second reaction gas RG2.

As shown in FIG. 12 and FIG. 14, in the forming S120 of the scattering layer on the emission material layer, the injection of the reaction gas STT3 may be started at about a same time as the application of the discharge power STT1 and the injection of the discharge gas STT2 (step S121). In an example, the forming S120 of the scattering layer on the emission material layer, the injection of the reaction gas STT3 may be started simultaneously with the application of the discharge power STT1 and the injection of the discharge gas STT2 (step S121). In addition, the injection of the reaction gas END3 may be ended at about a same time as the end of application of the discharge power END1 and the end of injection of the discharge gas END2 (step S122). In an example, the injection of the reaction gas END3 may be ended simultaneously with the end of application of the discharge power END1 and the end of injection of the discharge gas END2 (step S122).

As shown in FIG. 13 and FIG. 14, in the forming S130 of the first inorganic film on the scattering layer, the application of the discharge power STT1 and the injection of the discharge gas STT2 may be started after a certain period of time from the start of the injection of the reaction gas STT3 (step S131). In addition, the application of the discharge power END1 and the injection of the discharge gas END2 may be ended after a certain period of time from the end of the injection of the reaction gas END3 (step S132).

In the forming S130 of the first inorganic film on the scattering layer, the injection of the discharge gas CG and the application of the discharge power may be started after the injection of the reaction gas RG has been started, and the injection of the discharge gas CG and the application of the discharge power are ended after the end of the injection of the reaction gas RG, so that the reaction gas RG can be completely dissociated and settled on the first substrate 110 in the form of first radicals RDC1 and the second radicals RDC2. Accordingly, as shown in FIG. 17, polymers PLM may be formed by polymerization of the first radicals RDC1 and the second radicals RDC2 on the first substrate 110. The first inorganic film 171 may be formed by depositing these polymers PLM. The polymers PLM may include silicon nitride (SiNx), silicon oxide (SiOx), silicon oxynitride (SiOxNy), or the like.

As shown in FIG. 15, in the forming S120 of the scattering layer on the emission material layer, a part of the reaction gas RG may be completely dissociated and disposed on the first substrate 110 in the form of radicals RDC1 and RDC2. In the forming S120 of the scattering layer on the emission material layer, and in a case that the injection of reaction gas RG is started simultaneously with the start of the application of the discharge power and the start of the injection of the discharge gas CG, and the injection of the reaction gas RG is ended simultaneously with the end of the application of the discharge power and the end of the injection of the discharge gas CG, the remaining portion of the reaction gas RG may not be completely dissociated because it does not sufficiently absorb the discharge energy. As shown in FIG. 16, the remaining portion of the reaction gas RG may be disposed on the first substrate 110 in the form of a fragmented precursor FRG. The fragmented precursor FRG may include the reaction gas RG. For example, the fragmented precursor FRG may include silane (SiH₄) gas as the first reaction gas RG1, nitrous oxide (N₂O) as the second reaction gas RG2 and/or ammonia (NH₃) gas.

In the scattering layer SCT, the polymer PLM may be an aggregation of the completely dissociated radicals RDC1 and RDC2 and fragmented precursors FRG that are not completely dissociated, and the aggregation may form scattering particles AGL. That is to say, the scattering particles AGL may be formed by aggregating the polymer PLM with the fragmented precursors FRG. Such scattering particles AGL may form a plurality of convex portions CCV on the upper surface of the scattering layer SCT. In an example, the convex portions CCV may be formed as plasma particles, ion particles, etc., which may be generated in a deposition process of the method S1 (see FIG. 11), and the particles may be agglomerated by attraction.

According to the method S1, the scattering layer SCT including the scattering particles AGL may work as a guide film. For example, a light L1 emitted from the light-emitting layer LEL may transit the common electrode CME and the scattering layer SCT before reaching the first inorganic film 171. In doing so, light L2 may be refracted and scattered in various directions by the scattering particles AGL included in the scattering layer SCT. Accordingly, the amount of refracted and scattered light L2 reaching the color conversion elements included in the color conversion substrate 200 may be increased. As described herein, the color conversion substrate 200 may include the first wavelength conversion pattern WCL1, the second wavelength conversion pattern WCL2, and the transparent layer TPL. As a result, the luminous efficiency of the display device 1 can be improved.

In some embodiments, the forming S120 of the scattering layer on the emission material layer and the forming S130 of the first inorganic film on the scattering layer may be performed as continuous processes. For example, the forming S120 of the scattering layer on the emission material layer may take approximately several seconds (sec), and the forming S130 of the first inorganic film on the scattering layer may take approximately several tens of seconds (sec). Since the same reaction gas RG and discharge gas CG may be used to form the scattering layer SCT and the first inorganic film 171, the scattering layer SCT and the first inorganic film 171 may be formed via continuous processes in the same chamber using the same deposition apparatus DPS. Such continuous processes using the same equipment may be efficient. In an example in which no additional equipment is used for a process of adding the guide film, the process time can be shortened, and the process efficiency may be increased.

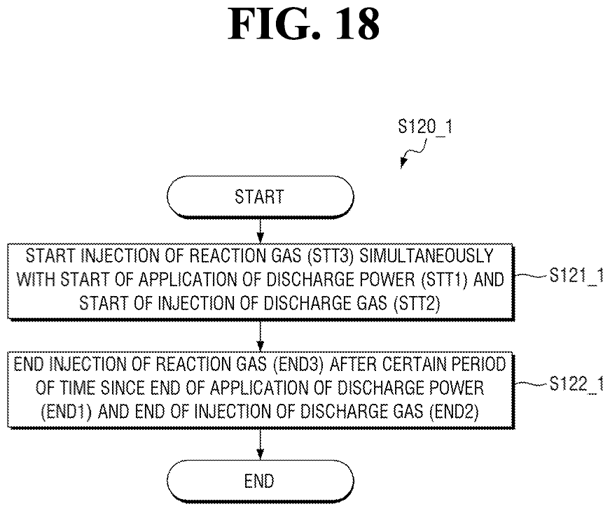

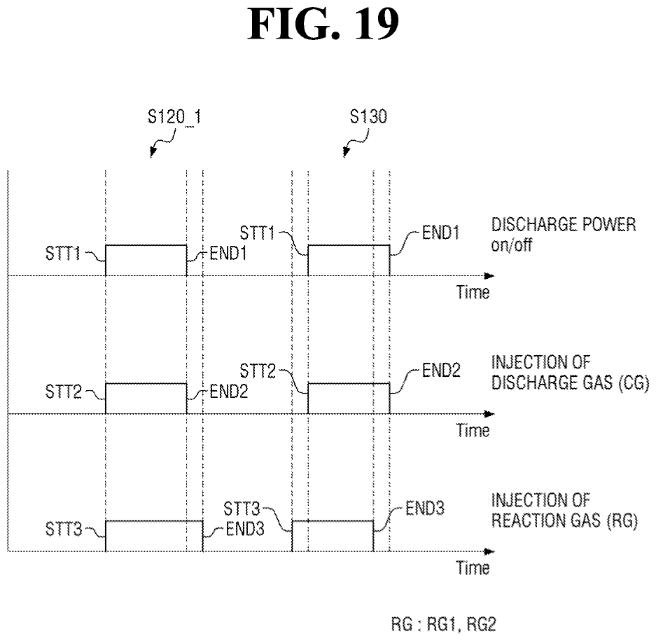

FIG. 18 is a flowchart for illustrating step S120 according to an embodiment of the present disclosure. FIG. 19 is a view for conceptually illustrating steps S120 and S130 according to an embodiment of the present disclosure. In the following description, the same or similar elements will be denoted by the same or similar reference numerals, and redundant descriptions may be omitted or briefly described.

The method S1 of fabricating a display device according to an embodiment of FIG. 18 and FIG. 19 includes forming the scattering layer on the emission material layer (step S120_1), wherein the injection of the reaction gas may be ended after a certain period of time from the end of the application of the discharge power and the end of the injection of the discharge gas.

More specifically, the forming S120_1 of the scattering layer on the emission material layer according to the method S1 may include starting the injection of the reaction gas STT3 at about a same time as the start of the application of the discharge power STT1 and the start of the injection of the discharge gas STT2 (step S121_1), and ending the injection of the reaction gas END3 after a certain period of time from the end of the application of the discharge power END1 and the end of the injection of the discharge gas END2 (step S122-1). The forming S120_1 of the scattering layer on the emission material layer may include starting the injection of the reaction gas STT3 simultaneously with the start of the application of the discharge power STT1 and the start of the injection of the discharge gas STT2 (step S121_1).

As shown in FIG. 18 and FIG. 19, in the forming S120_1 of the scattering layer on the emission material layer, the injection of the reaction gas STT3 may be started simultaneously with the application of the discharge power STT1 and the injection of the discharge gas STT2 (step S121-1).

In the forming S120_1 of the scattering layer on the emission material layer, the injection of the reaction gas END3 may be ended after a certain period of time from the end of the application of the discharge power END1 and the end of the injection of the discharge gas END2 (step S121-1).

According to the method S1 in which the injection of the reaction gas END3 may be ended after a certain period of time from the end of the application of the discharge power END1 and the end of injection of the discharge gas END2, the amount of reaction gases RG that is not completely dissociated may increase because the reaction gases RG cannot absorb sufficient discharge energy. That is to say, the amount of fragmented precursors FRG that are not completely dissociated into radicals RDC1 and RDC2 may increase. Accordingly, the number and size of the scattering particles AGL formed by aggregation of the polymer PLM with fragmented precursors FRG may increase. As a result, the light emitted from the light-emitting layer LEL can be scattered more widely by the scattering layer SCT, and the amount of light reaching the color conversion substrate 200 can be increased, thereby increasing the luminous efficiency of the display device 1.

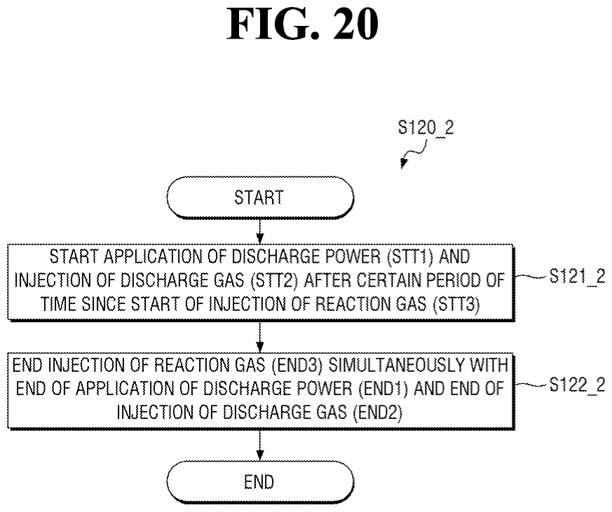

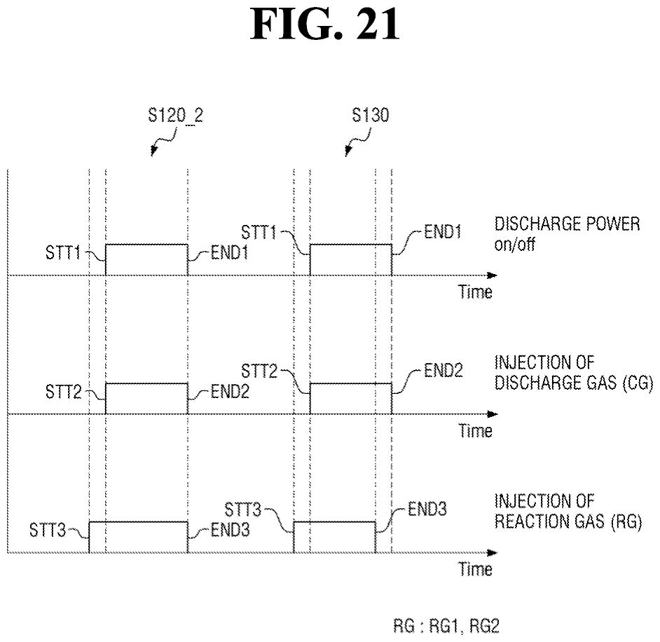

FIG. 20 is a flowchart for illustrating step S120 according to an embodiment of the present disclosure. FIG. 21 is a view for conceptually illustrating steps S120 and S130 according to an embodiment of the present disclosure.

The method S1 of fabricating a display device according to an embodiment of FIG. 20 and FIG. 21 may include forming the scattering layer on the emission material layer (step S120_2), wherein the application of the discharge power and the injection of the discharge gas are started after a certain period of time from the start of the application of the reaction gas.

More specifically, the forming S120_2 of the scattering layer on the emission material layer according to the method S1 may include starting the application of the discharge power STT1 and the injection of the discharge gas STT2 after a certain period of time from the start of the injection of the reaction gas STT3 (step S121_1), and ending the injection of the reaction gas END3 at about a same time as the end of the application of the discharge power END1 and the end of the injection of the discharge gas END2 (step S122_2). In an example, the injection of the reaction gas END3 may be ended simultaneously with the end of the application of the discharge power END1 and the end of the injection of the discharge gas END2 (step S122_2).

As shown in FIG. 20 and FIG. 21, in the forming S120_2 of the scattering layer on the emission material layer, the application of the discharge power STT1 and the injection of the discharge gas STT2 may be started after a certain period of time from the start of the injection of the reaction gas STT3 (step S121_1).

In the forming S120_2 of the scattering layer on the emission material layer, the injection of the reaction gas END3 may be ended at about a same time as the end of the application of the discharge power END1 and the end of the injection of the discharge gas END2 (step S121_2). In an example, the injection of the reaction gas END3 may be ended simultaneously with the end of the application of the discharge power END1 and the end of the injection of the discharge gas END2 (step S121_2).

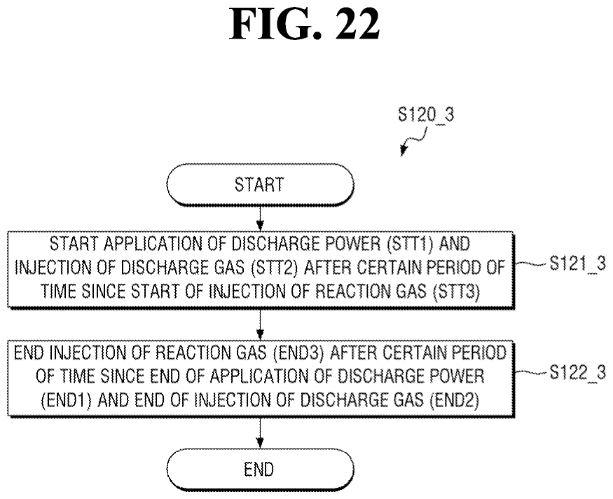

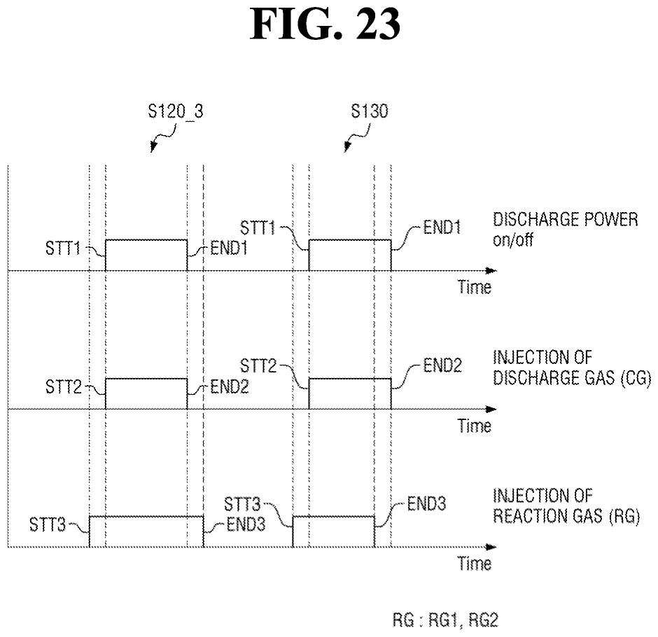

FIG. 22 is a flowchart for illustrating step S120 according to an embodiment of the present disclosure. FIG. 23 is a view for conceptually illustrating steps S120 and S130 according to an embodiment of the present disclosure.

The method S1 of fabricating a display device according to an embodiment of FIG. 22 and FIG. 23 may include forming the scattering layer on the emission material layer (step S120_3), wherein the injection of the reaction gas may be ended after a certain period of time from the end of the application of the discharge power and the end of the injection of the discharge gas.

More specifically, the forming S120_3 of the scattering layer on the emission material layer according to the method S1 may include starting the application of the discharge power STT1 and the injection of the discharge gas STT2 after a certain period of time from the start of the injection of the reaction gas STT3 (step S121_3), and ending the injection of the reaction gas END3 after a certain period of time from the end of the application of the discharge power END1 and the end of the injection of the discharge gas END2 (step $122_3).

As shown in FIG. 22 and FIG. 23, in the forming S120_3 of the scattering layer on the emission material layer, the application of the discharge power STT1 and the injection of the discharge gas STT2 may be started after a certain period of time from the start of the injection of the reaction gas STT3 (step $121_3).

In the forming S120_3 of the scattering layer on the emission material layer, the injection of the reaction gas END3 may be ended after a certain period of time from the end of the application of the discharge power END1 and the end of the injection of the discharge gas END2 (step S121_3).

According to the method S1 in which the injection of the reaction gas END3 may be ended after a certain period of time from the end of the application of the discharge power END1 and the end of injection of the discharge gas END2, the amount of reaction gases RG that is not completely dissociated may increase because the reaction gases RG cannot absorb sufficient discharge energy. That is to say, the amount of fragmented precursors FRG that is not completely dissociated into first radicals RDC1 and second radicals RDC2 may increase. Accordingly, the number and size of the scattering particles AGL formed by aggregation of the polymer PLM with fragmented precursors FRG may increase. As a result, the light emitted from the light-emitting layer LEL can be scattered more widely by the scattering layer SCT, and the amount of the light reaching the color conversion substrate 200 can be increased, thereby increasing the luminous efficiency of the display device 1.

According to an embodiment and referring to FIG. 14, FIG. 19, FIG. 21, and FIG. 23, the forming of the scattering layer S120 may include ending a first injection of a reaction gas simultaneously with or after ending a first application of a discharge power and a first injection of a discharge gas, and the forming of the first inorganic film S130 may include starting a second application of the discharge power and a second injection of the discharge gas after a predetermined period of time from a start of a second injection of the reaction gas, and ending the second application of the discharge power and the second injection of the discharge gas after a predetermined period of time from the end of the second injection of the reaction gas.

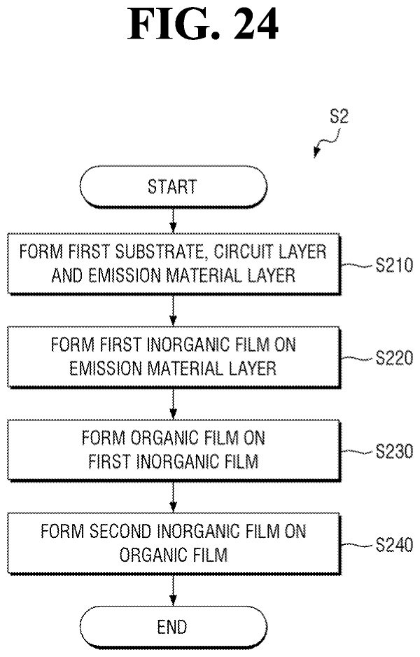

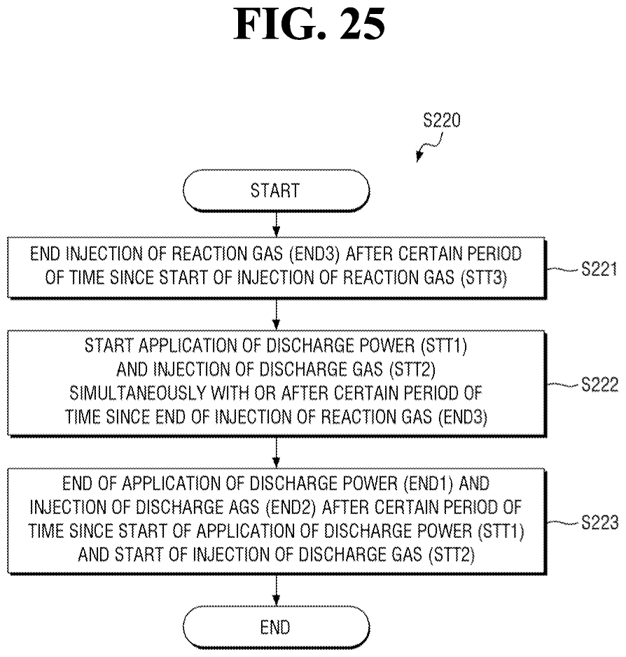

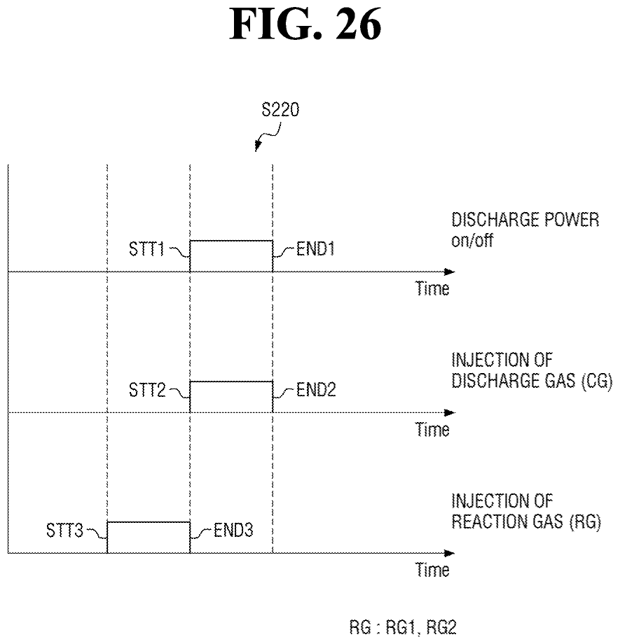

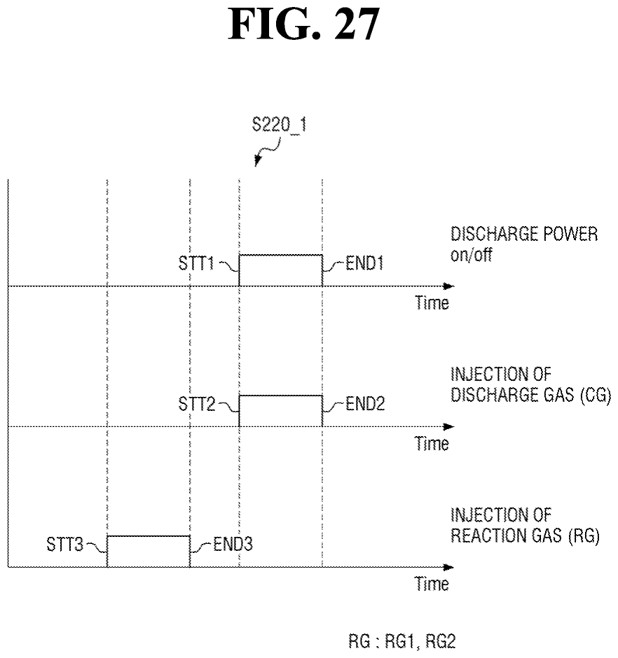

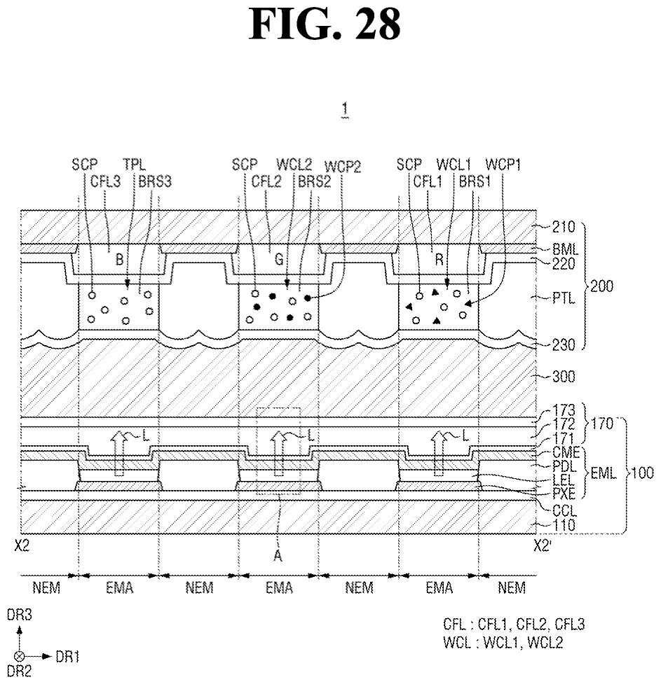

FIG. 24 is a flowchart for illustrating a method of fabricating a display device according to an embodiment. FIG. 25 is a flowchart for illustrating step S220 according to an embodiment of the present disclosure. FIG. 26 is a view for conceptually illustrating step S220 according to an embodiment of the present disclosure. FIG. 27 is a view for conceptually illustrating step S220 according to an embodiment of the present disclosure. FIG. 28 is a cross-sectional view illustrating an example of a display device fabricated by a method of fabricating a display device according to an embodiment.

A method S2 of fabricating a display device according to an embodiment may not include forming a scattering layer.

More specifically, the method S2 of fabricating a display device according to an embodiment (S2) may include forming a first substrate, a circuit layer, and an emission material layer (step S210); forming a first inorganic film on the emission material layer (step S220); forming an organic film on the first inorganic film (step S230); and forming a second inorganic film on the organic film (step S240).

The forming S210 of the first substrate, the circuit layer and the emission material layer of the method S2 of fabricating a display device may be substantially the same as the forming S110 of the substrate, the circuit layer and the emission material layer of the method S1 of fabricating a display device described herein; and, therefore, the redundant descriptions may be omitted.

Likewise, the forming S230 of the organic film on the first inorganic film of the method S2 of fabricating a display device may be substantially the same as the forming S140 of the organic film on the first inorganic film of the method S1 of fabricating a display device described herein; and, therefore, the redundant descriptions may be omitted.

In the method S2 of fabricating a display device according to an embodiment, the forming S220 of the first inorganic film on the emission material layer and the forming S240 of the second inorganic film on the organic film may be carried out via the same process. Thus, the forming S220 of the first inorganic film on the emission material layer may be mainly described for convenience of illustration.

In the forming S220 of the first inorganic film on the emission material layer, the first inorganic film 171 may be formed on the emission material layer EML. The first inorganic film 171 may include silicon nitride (SiNx), silicon oxide (SiOx), or silicon oxynitride (SiOxNy). As shown in FIG. 25, the forming S220 of the first inorganic film on the emission material layer may include ending the injection of the reaction gas END3 after a certain period of time from the start of injection of the reaction gas STT3 (step S221); starting the application of the discharge power STT1 and the injection of the discharge gas STT2 simultaneously with or after a certain period of time from the end of the injection of the reaction gas END3; and ending the application of the discharge power END1 and the injection of the discharge gas END2 after a certain period of time from the start of the application of the discharge power STT1 and the start of the injection of the discharge gas STT2 (step S223).

According to an embodiment, the forming S220 of the first inorganic film on the emission material layer and the forming S240 of the second inorganic film on the organic film may be carried out via the same process, and the forming of the second inorganic film may include starting a third application of the discharge power and a third injection of the discharge gas simultaneously with or after starting of a third injection of the reaction gas, and ending the third application of the discharge power and the third injection of the discharge gas simultaneously with or before ending of the third injection of the reaction gas.

According to an embodiment, the injection of the reaction gas RG may be started, and the injection of the reaction gas RG may be ended after a predetermined period of time, as shown in FIG. 26. The injection of the discharge gas CG and the application of the discharge power may be started when the injection of the reaction gas RG is ended. After a certain period of time, the injection of the discharge gas CG and the application of the discharge power may also be ended.

According to an embodiment, as shown in FIG. 27, the injection of the discharge gas CG and the application of the discharge power may be started at a same time after a predetermined period of time after the injection of the reaction gas RG is ended.

As the injection of the discharge gas CG and the application of the discharge power may be started simultaneously with or after a certain period of time from the end of the injection of the reaction gas RG, the injection process of the reaction gas RG and the discharging process may proceed at different times.

The reaction gas RG, which has received no discharge energy, may be disposed on the surface of the first substrate 110 as is, without any phase change due to intermolecular attraction such as van der Waals force. Intermolecular attraction, such as the van der Waals force, is a relatively weak force compared to chemical bonds. The reaction gas RG may be disposed on the surface of the first substrate 110 and have a thin thickness. As an example, the reaction gas RG may have a thickness on the order of several molecular layers or several atomic layers.

Subsequently, the discharging gas CG may be injected and the discharge power may be applied, so that the reaction gases RG disposed on the surface of the first substrate 110 may be completely dissociated into first radicals RDC1 and second radicals RDC2, which may chemically react with each other. As a result, the first inorganic film 171 including silicon nitride (SiNx), silicon oxide (SiOx), silicon oxynitride (SiOxNy), etc. may be formed. In an example, the first inorganic film 171 may have a thin thickness and a high density.

According to the method S2 of fabricating a display device, it may be possible to form the first inorganic film 171 that is thinner and has a higher density than the first inorganic film formed by a plasma-enhanced chemical vapor deposition process. Since the first inorganic film 171 has a high density, encapsulation performance can be high, and at the same time, the luminous efficiency of the display device 1 can be improved by reducing the thickness of the first inorganic film 171.

Although the method S2 of fabricating a display device according to an embodiment has been described separately from the method S1 of fabricating a display device according to an embodiment described with reference to FIG. 11, the method S2 may also be applied to fabricate the display device 1 according to an embodiment described with reference to FIG. 8 and the like. For example, the scattering layer SCT of the display device 1 according to an embodiment described with reference to FIG. 8 and the like may be formed according to the method S1 described with reference to FIG. 11, and the first inorganic film 171 may be formed on the scattering layer SCT according to the method S2. That is to say, the first inorganic film 171 of FIG. 28 may be formed on the scattering layer SCT of FIG. 8.

In concluding the detailed description, those skilled in the art will appreciate that many variations and modifications can be made to the preferred embodiments without substantially departing from the principles of the invention. Therefore, the disclosed preferred embodiments of the invention are used in a generic and descriptive sense only and not for purposes of limitation.

What is claimed is:

1. A display device comprising:
an emission material layer; and
an encapsulation structure disposed on the emission material layer and comprising a scattering layer, a first inorganic film disposed on the scattering layer, an organic film disposed on the first inorganic film, and a second inorganic film disposed on the organic film,
wherein the scattering layer comprises a plurality of convex portions.

2. The display device of claim 1,
wherein the plurality of convex portions comprise:
first particles comprising a same material as the first inorganic film; and
second particles comprising a material different from that of the first particles.

3. The display device of claim 2, wherein the first particles comprise at least one of silicon oxide, silicon nitride, or silicon oxynitride.

4. The display device of claim 3, wherein the second particles comprise a same material as the first particles, and comprise at least one of silane (SiH₄), nitrous oxide (N₂O), or ammonia (NH₃).

5. The display device of claim 1, wherein a thickness of the scattering layer ranges from about 0.3 to 0.75 times a thickness of the first inorganic film.

6. The display device of claim 1, wherein a thickness of the scattering layer ranges from about 0.3 μm to 0.5μ m.

7. The display device of claim 1, wherein each of the plurality of convex portions have a hemispherical shape.

8. The display device of claim 1, wherein an average radius of each of the plurality of convex portions ranges from about 0.15 μm to 0.25 μm.

9. The display device of claim 1, further comprising:
a first substrate;
a circuit layer disposed on the first substrate, wherein the emission material layer is disposed on the circuit layer;
a second substrate facing the first substrate and defining a first light-transmitting area, a second light-transmitting area, and a third light-transmitting area;
a color filter layer disposed on the second substrate and comprising a first color filter overlapping the first light-transmitting area, a second color filter overlapping the second light-transmitting area, and a third color filter overlapping the third light-transmitting area;
a first wavelength conversion layer disposed on the first color filter;
a second wavelength conversion layer disposed on the second color filter; and
a transparent layer disposed on the third color filter,
wherein the scattering layer is disposed between the first wavelength conversion layer, the second wavelength conversion layer and the transparent layer, and the emission material layer.

10. The display device of claim 1, wherein the scattering layer is configured to reduce reflectance of external light incident through a display surface.

11. A method of fabricating a display device, the method comprising:
forming an emission material layer;
forming a scattering layer on the emission material layer; and
forming a first inorganic film on the scattering layer,
wherein the forming of the scattering layer comprises ending an injection of a reaction gas simultaneously with or after ending an application of a discharge power and an injection of a discharge gas.

12. The method of claim 11, wherein the forming of the scattering layer comprises starting injection of the reaction gas simultaneously with or before starting the application of the discharge power and the injection of the discharge gas.

13. The method of claim 11, wherein the forming of the first inorganic film comprises:
starting a second application of the discharge power and a second injection of the discharge gas after a predetermined period of time from a start of a second injection of the reaction gas, and
ending the second application of the discharge power and the second injection of the discharge gas after a predetermined period of time from the end of the second injection of the reaction gas.

14. The method of claim 11, further comprising:
forming a first substrate and a circuit layer on the first substrate, wherein the emission material layer is formed on the circuit layer;
forming an organic film on the first inorganic film; and
forming a second inorganic film on the organic film,
wherein the forming of the second inorganic film comprises:
starting a third application of the discharge power and a third injection of the discharge gas simultaneously with or after starting a third injection of the reaction gas, and
ending the third application of the discharge power and the third injection of the discharge gas simultaneously with or before ending of the third injection of the reaction gas.

15. The method of claim 11, wherein the scattering layer comprises a plurality of convex portions.

16. The method of claim 15,
wherein the plurality of convex portions comprise:
first particles comprising a same material as the first inorganic film; and
second particles comprising a material different from that of the first particles.

17. The method of claim 16, wherein the first particles comprise at least one of silicon oxide, silicon nitride, or silicon oxynitride, and the second particles comprise a same material as the first particles, and comprise at least one of silane (SiH₄), nitrous oxide (N₂O), or ammonia (NH₃).

18. The method of claim 17, wherein a thickness of the scattering layer ranges from about 0.3 to 0.75 times a thickness of the first inorganic film.

19. A method of fabricating a display device, the method comprising:
forming a first substrate, a circuit layer on the first substrate, and an emission material layer on the circuit layer; and
forming a first inorganic film on the emission material layer,
wherein the forming of the first inorganic film comprises:
ending an injection of a reaction gas after a predetermined period of time from starting an application of the reaction gas, and
starting an application of a discharge power and an injection of a discharge gas simultaneously with or after ending the injection of the reaction gas.

20. The method of claim 19, wherein the application of the discharge power and the injection of the discharge gas are ended after a predetermined period of time from the start of the application of the discharge power and the injection of the discharge gas.
